(19) United States
(12) Patent Application Publication
(10) Pub. No.: US 2026/0182173 A1
(43) Pub. Date: Jun. 25, 2026

(54) Display Substrate and Display Device

(71) Applicants: Chengdu BOE Optoelectronics Technology Co., Ltd., Chengdu, Sichuan (CN); BOE Technology Group Co., Ltd., Beijing (CN)

(72) Inventors: Tiaomei ZHANG, Beijing (CN); Ming HU, Beijing (CN); Zhiliang JIANG, Beijing (CN); Haijun QIU, Beijing (CN); Lang LIU, Beijing (CN); Hongbo MA, Beijing (CN); Mingkun YANG, Beijing (CN); Zhen LIU, Beijing (CN); Jianpeng WU, Beijing (CN); Wenhui GAO, Beijing (CN)

(21) Appl. No.: 18/832,113

(22) PCT Filed: May 25, 2023
(86) PCT No.: PCT/CN2023/096186

§ 371 Date: Jul. 23, 2024

(51) Int. Cl. H10K 59/131; H10D 30/67; H10D 86/40; H10D 86/60; H10H 29/32; H10H 29/49; H10K 59/121; H10K 59/126

(52) U.S. Cl. CPC H10K 59/131; H10D 30/6733; H10H 29/32; H10H 29/49; H10K 59/1213; H10K 59/1216; H10K 59/126; H10D 86/441; H10D 86/60

(57) ABSTRACT

A display substrate includes multiple circuit units, a first power supply connection line, a second power supply connection line, a first power supply line, and a second power supply line, a circuit unit includes a pixel drive circuit, the first power supply line is connected to the pixel drive circuit, and is connected to the first power supply connection line, and the second power supply line is connected to the second power supply connection line; the pixel drive circuit includes a first shielding electrode and at least one transistor with a double-gate structure, an orthographic projection of the first shielding electrode on the base substrate is at least partially overlapped with that of a node between two gate electrodes of a transistor with the double-gate structure on the base substrate; the first shielding electrode is connected to a first power supply connection line or a second power supply connection line.

### CROSS-REFERENCE TO RELATED APPLICATIONS

The present application is a U.S. National Phase Entry of International Application PCT/CN2023/096186 having an international filing date of May 25, 2023, and entitled “Display Substrate and Display Device”, contents of which should be construed as being incorporated herein by reference.

### TECHNICAL FIELD

The present disclosure relates to, but is not limited to, the field of display technologies, and particularly relates to a display substrate and a display device.

### BACKGROUND

An organic light emitting diode (OLED for short) and a quantum dot light emitting diode (QLED for short) are active light emitting display devices and have advantages such as self-luminescence, wide viewing angle, high contrast ratio, low power consumption, very high response speed, lightness and thinness, flexibility, and low cost. With constant development of display technologies, a flexible display device (flexible display) in which an OLED or a QLED is used as a light emitting device and a thin film transistor (TFT for short) is used for signal control has become a mainstream product in the field of display at present.

### SUMMARY

The following is a summary of subject matter described herein in detail. This summary is not intended to limit the protection scope of claims.

In one aspect, the present disclosure provides a display substrate. The display substrate includes a drive circuit layer provided on a base substrate and a light emitting structure layer provided on a side of the drive circuit layer away from the base substrate. The drive circuit layer at least includes multiple circuit units. At least one first power supply connection line and at least one second power supply connection line extend along a first direction, and at least one first power supply line and at least one second power supply line extend along a second direction. At least one circuit unit includes a pixel drive circuit, and the first power supply line is connected to the pixel drive circuit. A first power supply line is configured to continuously provide a high-level signal to the pixel drive circuit, the light emitting structure layer at least includes multiple light emitting units, at least one light emitting unit includes a cathode, a second power supply line is connected to the cathode, and the second power supply line is configured to continuously provide a low-level signal to the cathode. The at least one first power supply line is connected to the at least one first power supply connection line to form a mesh structure for transmitting a first power supply signal, and the at least one second power supply line is connected to the at least one second power supply connection line to form a mesh structure for transmitting a second power supply signal. The first direction intersects with the second direction.

The pixel drive circuit includes a first shielding electrode and at least one transistor with a double-gate structure. An orthographic projection of the first shielding electrode on the base substrate is at least partially overlapped with an orthographic projection of a node between two gate electrodes of a transistor with the double-gate structure on the base substrate. The first shielding electrode is connected to a first power supply connection line; or, the first shielding electrode is connected to a second power supply connection line.

In some exemplary embodiments, the at least one transistor with the double-gate structure includes a first initialization transistor and a compensation transistor. A first electrode of the first initialization transistor is connected to a first initial signal line. A first electrode of the compensation transistor is connected to a second electrode of the first initialization transistor. The orthographic projection of the first shielding electrode on the base substrate is at least partially overlapped with an orthographic projection of a node between two gate electrodes of the first initialization transistor on the base substrate, and the orthographic projection of the first shielding electrode on the base substrate is at least partially overlapped with an orthographic projection of a node between two gate electrodes of the compensation transistor on the base substrate.

In some exemplary embodiments, the first shielding electrode and the second power supply connection line are interconnected to form an integral structure.

In some exemplary embodiments, the second power supply connection line is on a side of the first power supply connection line close to the first initialization transistor and the compensation transistor.

In some exemplary embodiments, the first shielding electrode at least includes a first sub-electrode and a second sub-electrode. A first end of the first sub-electrode is connected to the second power supply connection line, a second end of the first sub-electrode extends in a direction close to the first power supply connection line, and an orthographic projection of the second end of the first sub-electrode on the base substrate is at least partially overlapped with the orthographic projection of the node between the two gate electrodes of the first initialization transistor on the base substrate. A first end of the second sub-electrode is connected to the second power supply connection line, a second end of the second sub-electrode extends in the direction close to the first power supply connection line, and an orthographic projection of the second end of the second sub-electrode on the base substrate is at least partially overlapped with the orthographic projection of the node between the two gate electrodes of the compensation transistor on the base substrate.

In some exemplary embodiments, the first shielding electrode and the first power supply connection line are interconnected to form an integral structure.

In some exemplary embodiments, the first power supply connection line is on a side of the second power supply connection line close to the first initialization transistor and the compensation transistor.

In some exemplary embodiments, the first shielding electrode at least includes a third sub-electrode and a fourth sub-electrode. A first end of the third sub-electrode is connected to the first power supply connection line, a second end of the third sub-electrode extends in a direction close to the second power supply connection line, and an orthographic projection of the second end of the third sub-electrode on the base substrate is at least partially overlapped with the orthographic projection of the node between the two gate electrodes of the first initialization transistor on the base substrate. A first end of the fourth sub-electrode is connected to the first power supply connection line, a second end of the fourth sub-electrode extends in the direction close to the second power supply connection line, and an orthographic projection of the second end of the fourth sub-electrode on the base substrate is at least partially overlapped with the orthographic projection of the node between the two gate electrodes of the compensation transistor on the base substrate.

In some exemplary embodiments, the pixel drive circuit further includes a first storage capacitor and a second storage capacitor. The first storage capacitor at least includes a first plate and a third plate. An orthographic projection of the first plate on the base substrate is at least partially overlapped with an orthographic projection of the third plate on the base substrate; The second storage capacitor at least includes a second plate and a fourth plate, an orthographic projection of the second plate on the base substrate is at least partially overlapped with an orthographic projection of the fourth plate on the base substrate. The second plate is connected to the third plate, the fourth plate is connected to the first power supply connection line, and the first shielding electrode is connected to the fourth plate.

In some exemplary embodiments, the first shielding electrode and the fourth plate are interconnected to form an integral structure.

In some exemplary embodiments, the first shielding electrode includes a first extension segment and a first shielding segment. The first extension segment is in a strip shape extending along the second direction, and the first shielding segment is in a strip shape extending along the first direction. A first end of the first extension segment is connected to the fourth plate, and a second end of the first extension segment is connected to the first shielding segment. The first shielding segment includes a first shielding end and a second shielding end, an orthographic projection of the first shielding end on the base substrate is at least partially overlapped with an orthographic projection of a node between two gate electrodes of the first initialization transistor in a current circuit unit on the base substrate, and an orthographic projection of the second shielding end on the base substrate is at least partially overlapped with an orthographic projection of a node between two gate electrodes of a compensation transistor in an adjacent circuit unit on the base substrate.

In some exemplary embodiments, the at least one transistor with the double-gate structure further includes a data writing transistor and a first reference transistor, a first electrode of the data writing transistor is connected to a data signal line, a first electrode of the first reference transistor is connected to a first reference signal line, and a second electrode of the data writing transistor is connected to a second electrode of the first reference transistor.

The pixel drive circuit further includes a second shielding electrode provided between a first electrode of the data writing transistor and the second electrode of the data writing transistor.

In some exemplary embodiments, the at least one transistor with the double-gate structure further includes a data writing transistor and a first reference transistor, a first electrode of the data writing transistor is connected to a data signal line, a first electrode of the first reference transistor is connected to a first reference signal line, and a second electrode of the data writing transistor is connected to a second electrode of the first reference transistor.

The pixel drive circuit further includes a third shielding electrode and a fourth shielding electrode, an orthographic projection of the third shielding electrode on the base substrate is at least partially overlapped with an orthographic projection of a node between two gate electrodes of the data writing transistor on the base substrate, and an orthographic projection of the fourth shielding electrode on the base substrate is at least partially overlapped with an orthographic projection of a node between two gate electrodes of the first reference transistor on the base substrate.

In some exemplary embodiments, an orthographic projection of the second power supply connection line on the base substrate is at least partially overlapped with an orthographic projection of the first initial signal line on the base substrate.

In some exemplary embodiments, on a plane perpendicular to the display substrate, the drive circuit layer includes multiple conductive layers. The first power supply line and the first power supply connection line are provided in different conductive layers, and the first power supply line and the first power supply connection line are connected through a via. The second power supply line and the second power supply connection line are provided in different conductive layers, and the second power supply line and the second power supply connection line are connected through a via.

In some exemplary embodiments, the first power supply connection line and the second power supply connection line are provided in a same layer, and the first power supply line and the second power supply line are provided in a same layer.

In some exemplary embodiments, the multiple conductive layers at least include a first conductive layer, a second conductive layer, a third conductive layer, and a fourth conductive layer provided sequentially in a direction away from the base substrate. The first power supply connection line and the second power supply connection line are provided in the third conductive layer, and the first power supply line and the second power supply line are provided in the fourth conductive layer.

In some exemplary embodiments, on a plane perpendicular to the display substrate, the drive circuit layer includes multiple conductive layers. The multiple conductive layers at least include a first conductive layer, a second conductive layer, and a third conductive layer provided sequentially along a direction away from the base substrate. The first shielding electrode is provided in the second conductive layer, or the first shielding electrode is provided in the third conductive layer.

In some exemplary embodiments, the pixel drive circuit further includes a first storage capacitor and a second storage capacitor, the first storage capacitor at least includes a first plate and a third plate, an orthographic projection of the first plate on the base substrate is at least partially overlapped with an orthographic projection of the third plate on the base substrate. The second storage capacitor at least includes a second plate and a fourth plate, an orthographic projection of the second plate on the base substrate is at least partially overlapped with an orthographic projection of the fourth plate on the base substrate. The first plate and the second plate are provided in the first conductive layer, and the third plate and the fourth plate are provided in the second conductive layer.

In another aspect, the present disclosure also provides a display device, including the display substrate described above.

Other aspects of the present disclosure may be comprehended after the drawings and the detailed descriptions are read and understood.

### BRIEF DESCRIPTION OF DRAWINGS

Accompany drawings are intended to provide further understanding of technical solutions of the present disclosure and form a part of the specification. The accompany drawings and embodiments of the present disclosure are adopted to explain the technical solutions of the present disclosure, and do not form limitations on the technical solution of the present disclosure.

FIG. 1 is a schematic diagram of a structure of a display device.

FIG. 2 is a schematic diagram of a planar structure of a display substrate.

FIG. 3 is a schematic diagram of a sectional structure of a display substrate.

FIG. 4 is an equivalent circuit diagram of a pixel drive circuit according to an exemplary embodiment of the present disclosure.

FIG. 5 is a schematic diagram of a planar structure of a display substrate according to an exemplary embodiment of the present disclosure.

FIG. 6 is an enlarged view of regions of a first storage capacitor and a second storage capacitor in FIG. 5.

FIG. 7 is a schematic diagram of a display substrate after a pattern of a semiconductor layer is formed according to the present disclosure.

FIG. 8A and FIG. 8B are schematic diagrams of a display substrate after a pattern of a first conductive layer is formed according to the present disclosure.

FIG. 9A and FIG. 9B are schematic diagrams of a display substrate after a pattern of a second conductive layer is formed according to the present disclosure.

FIG. 10 is a schematic diagram of a display substrate after a pattern of a fourth insulation layer is formed according to the present disclosure.

FIG. 11A and FIG. 11B are schematic diagrams of a display substrate after a pattern of a third conductive layer is formed according to the present disclosure.

FIG. 12 is a schematic diagram of a display substrate after a pattern of a fifth insulation layer is formed according to the present disclosure.

FIG. 13A and FIG. 13B are schematic diagrams of a display substrate after a pattern of a fourth conductive layer is formed according to the present disclosure.

FIG. 14 is a schematic diagram of a planar structure of another display substrate according to an exemplary embodiment of the present disclosure.

FIG. 15 is an enlarged view of regions of a first storage capacitor and a second storage capacitor in FIG. 14.

FIG. 16A and FIG. 16B are schematic diagrams of another display substrate after a pattern of a third conductive layer is formed according to the present disclosure.

FIG. 17 is a schematic diagram of a planar structure of another display substrate according to an exemplary embodiment of the present disclosure.

FIG. 18 is an enlarged view of regions of a first storage capacitor and a second storage capacitor in FIG. 17.

FIG. 19A and FIG. 19B are schematic diagrams of another display substrate after a pattern of a third conductive layer is formed according to the present disclosure.

FIG. 20 is a schematic diagram of another display substrate after a pattern of a fifth insulation layer is formed according to the present disclosure.

FIG. 21A and FIG. 21B are schematic diagrams of another display substrate after a pattern of a fourth conductive layer is formed according to the present disclosure.

### REFERENCE SIGNS

| | | |
|---|---|---|
| 10-first active connection line; | 11-first active layer; | 12-second active layer; |
| 13-third active layer; | 14-fourth active layer; | 15-fifth active layer; |
| 16-sixth active layer; | 17-seventh active layer; | 18- eighth active layer; |
| 19-ninth active layer; | 20-second active connection line; | 21-first gate electrode; |
| 22-second gate electrode; | 24-fourth gate electrode; | 25-fifth gate electrode; |
| 26-sixth gate electrode; | 29-ninth gate electrode; | 31-first light emitting signal line; |
| 32-second light emitting signal line; | 33-repair line; | 36-first shielding electrode; |
| 37-second shielding electrode; | 38-third shielding electrode; | 39-fourth shielding electrode; |
| 41-first connection electrode; | 42-second connection electrode; | 43-third connection electrode; |
| 44-fourth connection electrode; | 45-fifth connection electrode; | 46-sixth connection electrode; |
| 47-seventh connection electrode; | 48-eighth connection electrode; | 49-ninth connection electrode; |
| 50-tenth connection electrode; | 51-first power supply line; | 52-second power supply line; |
| 53-data signal line; | 54-reference signal connection line; | 55-anode connection electrode; |
| 61-first scan signal line; | 62-second scan signal line; | 63-third scan signal line; |
| 64-fourth scan signal line; | 65-fifth scan signal line; | 68-first power supply connection line; |
| 69-second power supply connection line; | 71-first plate; | 72-second plate; |
| 73-third plate; | 74-fourth plate; | 75-first opening; |
| 76-second opening; | 81-first initial signal line; | 82-second initial signal line; |
| 91-first reference signal line; | 92-second reference signal line; | 101-base substrate; |
| 102-drive circuit layer; | 103-light emitting structure layer; | 104-encapsulation structure layer. |

### DETAILED DESCRIPTION

Embodiments of the present disclosure will be described in detail hereinafter with reference to the accompany drawings. It is to be noted that implementations may be implemented in multiple different forms. Those of ordinary skills in the art can easily understand such a fact that implementations and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one implementation of the present disclosure is not limited to shapes, numerical values, or the like shown in the drawings.

Ordinal numerals “first”, “second”, “third”, and the like in the specification are set not to form limits in numbers but only to avoid confusion between composition elements.

In the specification, for convenience, expressions “central”, “above”, “below”, “front”, “back”, “vertical”, “horizontal”, “top”, “bottom”, “inside”, “outside”, and the like indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements may be changed as appropriate according to a direction according to which each constituent element is described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be a fixed connection, or a detachable connection, or an integral connection; it may be a mechanical connection or an electrical connection; it may be a direct connection, or an indirect connection through a middleware, or internal communication between two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as the “source terminal” and the “drain terminal”, are interchangeable in the specification.

In the specification, “electrical connection” includes connection of composition elements through an element with a certain electrical action. An “element with a certain electrical action” is not particularly limited as long as electrical signals between the connected constituent elements may be sent and received. Examples of the “element with the certain electrical action” not only include an electrode and a wiring, but also include a switching element such as a transistor, a resistor, an inductor, a capacitor, another element with various functions, or the like.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive thin film” sometimes. Similarly, an “insulation film” may be replaced with an “insulation layer” sometimes.

Triangle, rectangle, trapezoid, pentagon, hexagon, and the like in this specification are not strictly defined, and they may be approximate triangle, rectangle, trapezoid, pentagon, hexagon, and the like. There may be some small deformations caused by tolerance, and there may be chamfer, arc edge, deformation, and the like.

In the present disclosure, “about” refers to that a boundary is not defined so strictly and numerical values within a range of process and measurement errors are allowed.

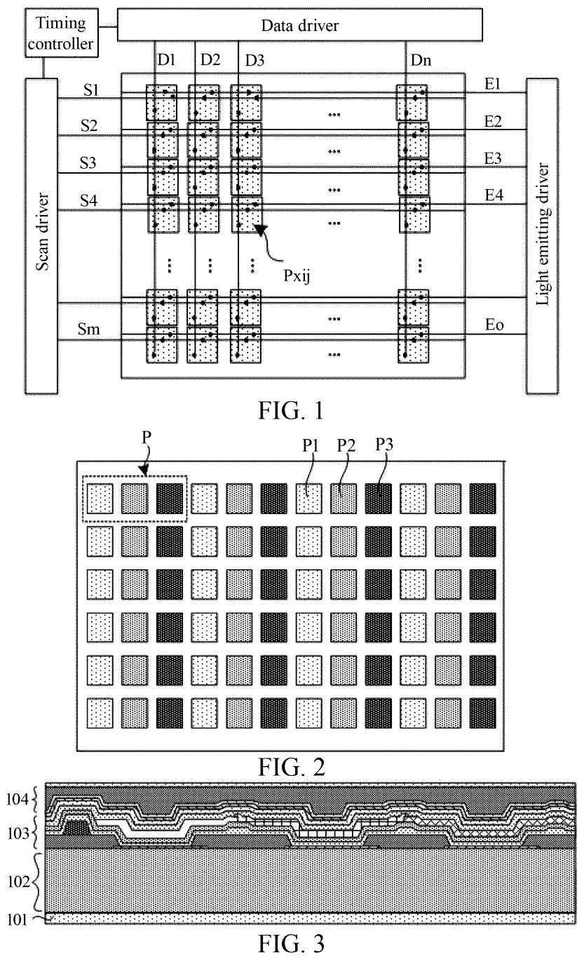

FIG. 1 is a schematic diagram of a structure of a display device. As shown in FIG. 1, the display device may include a timing controller, a data driver, a scan driver, a light emitting driver, and a pixel array. The timing controller is connected to the data driver, the scan driver, and the light emitting driver respectively. The data driver is connected to multiple data signal lines (D1 to Dn) respectively. The scan driver is connected to multiple scan signal lines (S1 to Sm) respectively. The light emitting driver is connected to multiple light emitting signal lines (E1 to Eo) respectively. A pixel array may include multiple sub-pixels Pxij, i and j may be natural numbers. At least one sub-pixel Pxij may include a circuit unit and a light emitting unit, and the circuit unit may at least include a pixel drive circuit. The pixel drive circuit is connected to a scan signal line, a light emitting signal line, and a data signal line respectively. The light emitting unit may include a light emitting device. The light emitting device is connected to the pixel drive circuit of the circuit unit. In an exemplary implementation, the timing controller may provide the data driver with a grayscale value and a control signal which are suitable for the specification of the data driver, provide the scan driver with a clock signal and a scan start signal and the like which are suitable for the specification of the scan driver, and provide the light emitting driver with a clock signal and an emission stop signal and the like which are suitable for the specification of the light emitting driver. The data driver may generate data voltages to be provided to the data signal lines D1, D2, D3, . . . , and Dn using the grayscale value and the control signal that are received from the timing controller. For example, the data driver may sample the grayscale value using the clock signal and apply a data voltage corresponding to the grayscale value to the data signal lines D1 to Dn by taking a pixel row as a unit, wherein n may be a natural number. The scan driver may generate a scan signal to be provided to the scan signal lines S1, S2, S3, . . . , and Sm by receiving the clock signal and the scan start signal and the like from the timing controller. For example, the scan driver may sequentially provide a scan signal with an on-level pulse to the scan signal lines S1 to Sm. For example, the scan driver may be constructed in a form of a shift register and may generate a scan signal in a manner in which a scan start signal provided in a form of an on-level pulse is transmitted to a next-stage circuit sequentially under control of the clock signal, wherein m may be a natural number. The light emitting driver may receive a clock signal, an emission stop signal, and the like from the timing controller to generate an emission signal to be provided to the light emitting signal lines E1, E2, E3, . . . , and Eo. For example, the light emitting driver may sequentially provide an emission signal with an off-level pulse to the light emitting signal lines E1 to Eo. For example, the light emitting driver may be constructed in a form of a shift register and generate an emission signal in a manner of sequentially transmitting an emission stop signal provided in a form of an off-level pulse to a next-stage circuit under control of the clock signal, wherein o may be a natural number. In an exemplary implementation, the pixel array may be provided on the display substrate.

FIG. 2 is a schematic diagram of a planar structure of a display substrate. In an exemplary implementation, the display substrate may include a display area and a bezel area located on a periphery of the display area. As shown in FIG. 2, the display area of the display substrate may include multiple pixel units P arranged in a matrix. At least one pixel unit P may include a first sub-pixel P1 emitting light of a first color, a second sub-pixel P2 emitting light of a second color, and a third sub-pixel P3 emitting light of a third color. Each sub-pixel may include a circuit unit and a light emitting unit. The circuit unit may at least include a pixel drive circuit, the pixel drive circuit is connected to a scan signal line, a data signal line, and a light emitting signal line respectively, and is configured to receive a data voltage transmitted by the data signal line and output a corresponding current to a light emitting device under control of the scan signal line and the light emitting signal line. The light emitting unit may at least include a light emitting device, the light emitting device is connected to a pixel drive circuit of a sub-pixel where the light emitting device is located, and the light emitting device is configured to emit light with a corresponding brightness in response to a current output by the pixel drive circuit of the sub-pixel where the light emitting device is located.

In an exemplary implementation, the first sub-pixel P1 may be a red (R) sub-pixel emitting red light, the second sub-pixel P2 may be a blue (B) sub-pixel emitting blue light, and the third sub-pixel P3 may be a green (G) sub-pixel emitting green light. In an exemplary implementation, a sub-pixel may be in a shape of a rectangle, a rhombus, a pentagon, or a hexagon. Three sub-pixels may be arranged in a manner to stand side by side horizontally, in a manner to stand side by side vertically, in a delta-shaped arrangement or the like, which is not limited here in the present disclosure.

In an exemplary implementation, a pixel unit may include four sub-pixels, and the four sub-pixels may be arranged in a manner to stand side by side horizontally, in a manner to stand side by side vertically, or in a manner to form a square, which is not limited here in the present disclosure.

FIG. 3 is a schematic diagram of a sectional structure of a display substrate, and illustrates a structure of three sub-pixels in the display substrate. As shown in FIG. 3, on a plane perpendicular to the display substrate, the display area of the display substrate may include a drive circuit layer 102 provided on a base substrate 101, a light emitting structure layer 103 provided on a side of the drive circuit layer 102 away from the base substrate 101, and an encapsulation structure layer 104 provided on a side of the light emitting structure layer 103 away from the base substrate 101. In some possible implementations, the display substrate may include another film layer, such as a touch structure layer, which is not limited here in the present disclosure.

In an exemplary implementation, the base substrate 101 may be a flexible base substrate, or may be a rigid base substrate. A material of the rigid base substrate may be, but is not limited to, one or more of glass and quartz. The flexible base substrate may be, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber.

In an exemplary implementation, the drive circuit layer 102 may include multiple circuit units, a circuit unit may include at least a pixel drive circuit, and the pixel drive circuit may include multiple transistors and a storage capacitor. The light emitting structure layer 103 may include multiple light emitting units, a light emitting unit may at least include a light emitting device, and the light emitting device may include an anode, an organic emitting layer, and a cathode. The anode is connected to a pixel drive circuit. The organic emitting layer is connected to the anode. The cathode is connected to the organic emitting layer. The organic emitting layer emits light of a corresponding color under driving of the anode and the cathode.

In an exemplary implementation, the encapsulation structure layer 104 may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer is provided between the first encapsulation layer and the third encapsulation layer to form a stacked structure of inorganic material/organic material/inorganic material, which may ensure that external moisture cannot enter the light emitting structure layer 103.

In an exemplary implementation, the organic emitting layer may include an emitting layer (EML for short), and any one or more of following layers: a hole injection layer (HIL for short), a hole transport layer (HTL for short), an electron block layer (EBL for short), a hole block layer (HBL for short), an electron transport layer (ETL for short), and an electron injection layer (EIL for short).

An exemplary embodiment of the present disclosure provides a display substrate. The display substrate includes a drive circuit layer provided on a base substrate and a light emitting structure layer provided on a side of the drive circuit layer away from the base substrate. The drive circuit layer at least includes multiple circuit units, at least one first power supply connection line and at least one second power supply connection line which extend along a first direction, and at least one first power supply line and at least one second power supply line which extend along a second direction. At least one circuit unit includes a pixel drive circuit, a first power supply line is connected to the pixel drive circuit, and the first power supply line is configured to continuously provide a high-level signal to the pixel drive circuit. The light emitting structure layer at least includes multiple light emitting units, and at least one light emitting unit includes a cathode. A second power supply line is connected to the cathode, and the second power supply line is configured to continuously provide a low-level signal to the cathode. The at least one first power supply line is connected to the at least one first power supply connection line to form a mesh structure for transmitting a first power supply signal. The at least one second power supply line is connected to the at least one second power supply connection line to form a mesh structure for transmitting a second power supply signal. The first direction intersects with the second direction.

The pixel drive circuit includes a first shielding electrode and at least one transistor with a double-gate structure. An orthographic projection of the first shielding electrode on the base substrate is at least partially overlapped with an orthographic projection of a node between two gate electrodes of the transistor with the double-gate structure on the base substrate. The first shielding electrode is connected to a first power supply connection line; or, the first shielding electrode is connected to a second power supply connection line.

In an exemplary implementation, the at least one transistor with the double-gate structure includes a first initialization transistor and a compensation transistor. A first electrode of the first initialization transistor is connected to a first initial signal line and a first electrode of the compensation transistor is connected to a second electrode of the first initialization transistor. An orthographic projection of the first shielding electrode on the base substrate is at least partially overlapped with an orthographic projection of a node between two gate electrodes of the first initialization transistor on the base substrate, and the orthographic projection of the first shielding electrode on the base substrate is at least partially overlapped with an orthographic projection of a node between two gate electrodes of the compensation transistor on the base substrate.

In an exemplary implementation, the first shielding electrode and the first power supply connection line are interconnected to form an integral structure.

In an exemplary implementation, the first shielding electrode and the second power supply connection line are interconnected to form an integral structure.

In an exemplary implementation, the pixel drive circuit further includes a first storage capacitor and a second storage capacitor. The first storage capacitor at least includes a first plate and a third plate, and an orthographic projection of the first plate on the substrate is at least partially overlapped with an orthographic projection of the third plate on the base substrate. The second storage capacitor at least includes a second plate and a fourth plate, and an orthographic projection of the second plate on the base substrate is at least partially overlapped with an orthographic projection of the fourth plate on the base substrate. The second plate is connected to the third plate, the fourth plate is connected to the first power supply connection line, and the first shielding electrode is connected to the fourth plate.

In an exemplary implementation, the first shielding electrode and the fourth plate are interconnected to form an integral structure.

The display substrate of the present disclosure is illustrated with examples below through some exemplary embodiments.

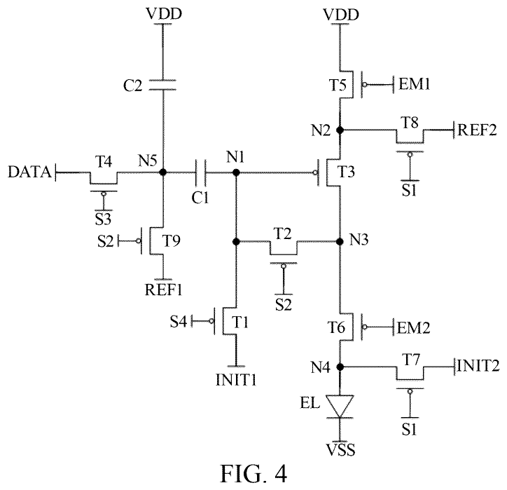

FIG. 4 is an equivalent circuit diagram of a pixel drive circuit according to an exemplary embodiment of the present disclosure. In an exemplary implementation, the pixel drive circuit may have a structure of 3TIC, 4TIC, 5TIC, 5T2C, 6TIC, 7TIC, 8TIC or 9T2C. As shown in FIG. 4, the pixel drive circuit of an exemplary embodiment of the present disclosure may be of a 9T2C structure and may include nine transistors (a first transistor T1 to a ninth transistor T9) and two storage capacitors (a first storage capacitor C1 and a second storage capacitor C2), and the pixel drive circuit is connected to 12 signal lines (first scan signal line S1, second scan signal line S2, third scan signal line S3, fourth scan signal line S4, first light emitting signal line EM1, second light emitting signal line EM2, first initial signal line INIT1, second initial signal line INIT2, first reference signal line REF1, second reference signal line REF2, data signal line DATA and first power supply line VDD) respectively.

In an exemplary implementation, the pixel drive circuit may include a first node N1, a second node N2, a third node N3, a fourth node N4, and a fifth node N5. The first node N1 is connected to a second electrode of the first transistor, a first electrode of the second transistor T2, a gate electrode of the third transistor T3, and a first end of the first storage capacitor C1, respectively. The second node N2 is connected to a first electrode of the third transistor T3, a second electrode of the eighth transistor T8, and a second electrode of the fifth transistor T5, respectively. The third node N3 is connected to a second electrode of the second transistor T2, a second electrode of the third transistor T3, and a first electrode of the sixth transistor T6, respectively. The fourth node N4 is connected to a second electrode of the sixth transistor T6, and a second electrode of the seventh transistor T7, respectively. The fifth node N5 is connected to a second electrode of the fourth transistor T4, a second electrode of the ninth transistor T9, a second end of the first storage capacitor C1, and a second end of the second storage capacitor C2, respectively.

In an exemplary implementation, a first end (a lower plate) of the first storage capacitor C1 is connected to the first node N1, and a second end (an upper plate) of the first storage capacitor C1 is connected to the fifth node N5. A first end (an upper plate) of the second storage capacitor C2 is connected to the first power supply line VDD and a second end (a lower plate) of the second storage capacitor C2 is connected to the fifth node N5.

In an exemplary implementation, a gate electrode of the first transistor T1 is connected to the fourth scan signal line S4, a first electrode of the first transistor T1 is connected to the first initial signal line INIT1, and the second electrode of the first transistor T1 is connected to the first node N1. When a turned-on signal is applied to the fourth scan signal line S4, the first transistor T1 transmits a first initial voltage to the gate electrode of the third transistor T3 and the first end of the first storage capacitor C1, thereby releasing charges accumulated in the first storage capacitor C1 and realizing initialization.

In an exemplary implementation, a control electrode of the second transistor T2 is connected to the second scan signal line S2, the first electrode of the second transistor T2 is connected to the first node N1, and the second electrode of the second transistor T2 is connected to the third node N3. When a turned-on signal is applied to the second scan signal line S2, the second transistor T2 enables the gate electrode of the third transistor T3 to be connected to the second electrode of the third transistor T3.

In an exemplary implementation, the gate electrode of the third transistor T3 is connected to the first node N1, i.e., the gate electrode of the third transistor T3 is connected to the first end of the first storage capacitor C1, the first electrode of the third transistor T3 is connected to the second node N2, and the second electrode of the third transistor T3 is connected to the third node N3. The third transistor T3 may be referred to as a drive transistor and the third transistor T3 determines a magnitude of the drive current according to a potential difference between the gate electrode and the first electrode of the third transistor T3.

In an exemplary implementation, a gate electrode of the fourth transistor T4 is connected to the third scan signal line S3, a first electrode of the fourth transistor T4 is connected to the data signal line Data, and the second electrode of the fourth transistor T4 is connected to the fifth node N5. When a turned-on signal is applied to the third scan signal line S3, the fourth transistor T4 inputs a data voltage of the data signal line DATA to the second end of the first storage capacitor C1 and the second end of the second storage capacitor C2.

In an exemplary implementation, a gate electrode of the fifth transistor T5 is connected to the first light emitting signal line EM1, a first electrode of the fifth transistor T5 is connected to the first power supply line VDD, and the second electrode of the fifth transistor T5 is connected to the second node N2. A gate electrode of the sixth transistor T6 is connected to the second light emitting signal line EM2, the first electrode of the sixth transistor T6 is connected to the third node N3, and the second electrode of the sixth transistor T6 is connected to the fourth node N4. When a turned-on signal is applied to the first light emitting signal line EM1 and the second light emitting signal line EM2, the fifth transistor T5 and the sixth transistor T6 form a drive current path between the first power supply line VDD and the second power supply line VSS to enable the light emitting device EL to emit light.

In an exemplary implementation, a gate electrode of the seventh transistor T7 is connected to the first scan signal line S1, a first electrode of the seventh transistor T7 is connected to the second initial signal line INIT2, and the second electrode of the seventh transistor T7 is connected to the fourth node N4. When a turned-on signal is applied to the first scan signal line S1, the seventh transistor T7 transmits a second initial voltage to a first electrode of the light emitting device EL, so that accumulated charges in the first electrode of the light emitting device EL is released and initialization is realized.

In an exemplary implementation, a gate electrode of the eighth transistor T8 is connected to the first scan signal line S1, a first electrode of the eighth transistor T8 is connected to the second reference signal line REF2, and the second electrode of the eighth transistor T8 is connected to the second node N2. When a turned-on signal is applied to the first scan signal line S1, the eighth transistor T8 transmits a second reference signal to the second node N2.

In an exemplary implementation, a gate electrode of the ninth transistor T9 is connected to the second scan signal line S2, a first electrode of the ninth transistor T9 is connected to the first reference signal line REF1, and the second electrode of the ninth transistor T9 is connected to the fifth node N5. When a turned-on signal is applied to the second scan signal line S2, the ninth transistor T9 transmits the first reference signal to the fifth node N5.

In an exemplary implementation of the present disclosure, the first transistor T1 may be referred to as a first initialization transistor, the second transistor T2 may be referred to as a compensation transistor, the third transistor T3 may be referred to as a drive transistor, the fourth transistor T4 may be referred to as a data writing transistor, the fifth transistor T5 may be referred to as a first light emitting transistor, the sixth transistor T6 may be referred to as a second light emitting transistor, the seventh transistor T7 may be referred to as a second initialization transistor, the eighth transistor T8 may be referred to as a second reference transistor, and the ninth transistor T9 may be referred to as a first reference transistor.

In an exemplary implementation, the light emitting device EL may be an OLED including a first electrode (anode), an organic emitting layer, and a second electrode (cathode) that are stacked, or may be a QLED including a first electrode (anode), a quantum dot light emitting layer, and a second electrode (cathode) that are stacked. The first electrode of the light emitting device EL is connected to the fourth node N4, the second electrode of the light emitting device EL is connected to the second power supply line VSS, a signal of the second power supply line VSS is a low-level signal continuously provided, and a signal of the first power supply line VDD is a high-level signal continuously provided.

In an exemplary implementation, the first transistor T1 to the ninth transistor T9 may be P-type transistors, or may be N-type transistors. Use of a same type of transistors in a pixel drive circuit may simplify a process flow, reduce a process difficulty of a display panel, and improve a product yield. In some possible implementations, the first transistor T1 to the ninth transistor T9 may include a P-type transistor and an N-type transistor.

In an exemplary implementation, the first transistor T1 to the ninth transistor T9 may employ a low-temperature poly-crystalline silicon thin film transistor, or may employ an oxide thin film transistor, or may employ a low-temperature poly-crystalline silicon thin film transistor and an oxide thin film transistor. An active layer of a low temperature poly-crystalline silicon thin film transistor may be made of Low Temperature Poly-crystalline silicon (LTPS for short), and an active layer of an oxide thin film transistor may be made of an oxide semiconductor (Oxide). A low temperature poly-crystalline silicon thin film transistor has advantages such as high mobility and fast charging, and the oxide thin film transistor has advantages, for example, a low leakage current. The low temperature poly-crystalline silicon thin film transistor and the oxide thin film transistor are integrated on one display substrate, that is a LTPS+Oxide (LTPO for short) display substrate, so that advantages of the low temperature poly-crystalline silicon thin film transistor and the oxide thin film transistor may be utilized, low-frequency drive may be achieved, power consumption may be reduced, and display quality may be improved.

In an exemplary implementation, a working process of the pixel drive circuit shown in FIG. 4 may include a first stage to a fifth stage.

First stage: the first stage may include multiple sub-stages that are repeatedly executed, and each sub-stage may include a first sub-stage and a second sub-stage that are sequentially executed.

In the first sub-stage, signals of the fourth scan signal line S4 and the first light emitting signal line EM1 are turned-on signals, and signals of other signal lines are turned-off signals. A signal of the fourth scan signal line S4 is a turned-on signal so that the first transistor T1 is turned on, and a first initial signal of the first initial signal line INIT1 may be provided to the first node N1 to initialize the first node N1. When the third transistor T3 is a P-type transistor, the third transistor T3 is turned on. A turned-on signal of the first light emitting signal line EM1 may enable the fifth transistor T5 to be turned on, and a first power supply signal of the first power supply line VDD may be provided to the second node N2.

In the second sub-stage, signals of the second scan signal line S2 and the first light emitting signal line EM1 are turned-on signals, and signals of other signal lines are turned-off signals. A signal of the second scan signal line S2 is a turned-on signal, so that the second transistor T2 can be turned on, the first node N1 and the third node N3 are connected to each other, and a threshold voltage of the third transistor T3 is written to the first node N1. The signal of the second scan signal line S2 is the turned-on signal, so that the ninth transistor T9 can be turned on, and a first reference signal of the first reference signal line REF1 is provided to the fifth node N5 to initialize the fifth node N5. The turned-on signal of the first light emitting signal line EM1 may enable the fifth transistor T5 to be turned on, and the first power supply signal of the first power supply line VDD may be provided to the second node N2.

Second stage: a signal of the third scan signal line S3 is a turned-on signal and signals of other signal lines are turned-off signals. The signal of the third scan signal line S3 is the turned-on signal, so that the fourth transistor T4 can be turned on, and a data voltage provided by the data signal line DATA is written to the fifth node N5.

Third stage: a signal of the first scan signal line S1 is a turned-on signal, and signals of other signal lines are turned-off signals. The signal of the first scan signal line S1 is the turned-on signal, so that the seventh transistor T7 can be turned on, and a second initial signal of the second initial signal line INIT2 may be written to the fourth node N4 to initialize the fourth node N4, so as to avoid residual signal of a previous frame affecting displaying of the current frame. The signal of the first scan signal line S1 is the turned-on signal, so that the eighth transistor T8 can be turned on, and the second reference signal of the second reference signal line REF2 may be written to the second node N2.

Fourth stage: a signal of the second light emitting signal line EM2 is a turned-on signal, and signals of other signal lines are turned-off signals. The signal of the second light emitting signal line EM2 is the turned-on signal, so that the sixth transistor T6 can be turned on, and the third node N3 and the fourth node N4 are connected to each other so that potentials of the third node N3 and the fourth node N4 are the same.

Fifth stage: signals of the first light emitting signal line EM1 and the second light emitting signal line EM2 are turned-on signals, and signals of other signal lines are turned-off signals. The signals of the first light emitting signal line EM1 and the second light emitting signal line EM2 are the turned-on signals, so that the fifth transistor T5 and the sixth transistor T6 can be turned on, and the first power supply signal of the first power supply line VDD may provide drive a signal to the light emitting device EL through the turned-on fifth transistor T5, the third transistor T3, and the sixth transistor T6 to drive the light emitting device EL to emit light.

In an exemplary implementation, since the drive transistor (i.e., the third transistor T3) is in one state for a long time, electrons are trapped in traps, resulting in hysteresis. Thus, in the first stage, not only hysteresis of the drive transistor may be reduced, but also a potential stability of the first node N1 may be ensured by performing an initialization and threshold voltage writing process on the first node N1 for several times (for example, three times). In the third stage, the second reference signal is written to the second node N2, and by changing a potential of the second node N2, the hysteresis of the drive transistor can be reduced. In the fourth stage, by connecting the third node N3 with the fourth node N4, a potential of the fourth node N4 may be raised, which is beneficial to reducing time required for reaching a turned-on voltage of the light emitting device.

The pixel drive circuit provided by the present disclosure can effectively improve hysteresis condition of the drive transistor and is beneficial to improving a display effect.

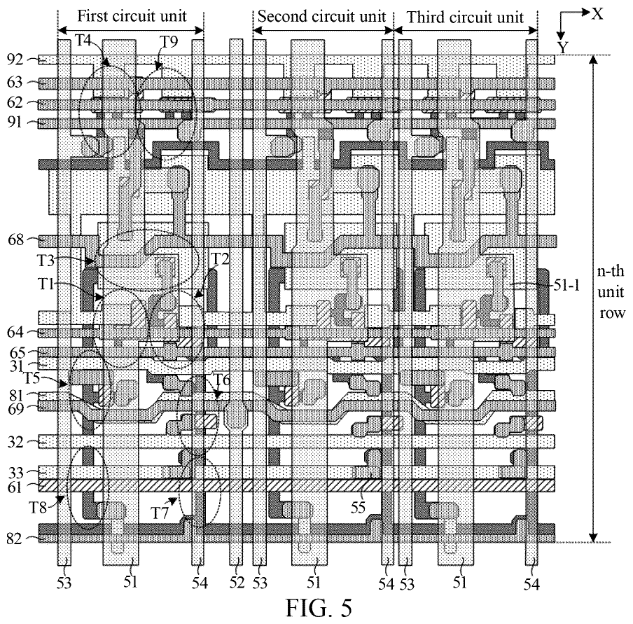

FIG. 5 is a schematic diagram of a planar structure of a display substrate according to an exemplary embodiment of the present disclosure, and illustrates a structure of pixel drive circuits in three circuit units (a first circuit unit, a second circuit unit, and a third circuit unit) in the display substrate. In an exemplary implementation, the display substrate may include a drive circuit layer provided on the base substrate and a light emitting structure layer provided on a side of the drive circuit layer away from the base substrate. The drive circuit layer may at least include multiple circuit units, the light emitting structure layer may at least include multiple light emitting units. At least one circuit unit includes a pixel drive circuit, and at least one light emitting unit includes a light emitting device. The light emitting device may at least include an anode, an organic emitting layer, and a cathode and the anode in the light emitting unit is connected to a pixel drive circuit in a corresponding circuit unit. In an exemplary implementation, the circuit units mentioned in the present disclosure refer to regions divided according to pixel drive circuits, and light emitting units mentioned in the present disclosure refer to regions divided according to light emitting devices. In an exemplary embodiment, a position of an orthographic projection of a light emitting unit on the base substrate may correspond to a position of an orthographic projection of a circuit unit on the base substrate, or the position of the orthographic projection of the light emitting unit on the base substrate may not correspond to the position of the orthographic projection of the circuit unit on the base substrate.

In an exemplary embodiment, multiple circuit units sequentially provided along a first direction X are referred to as a unit row, and multiple circuit units sequentially provided along a second direction Y are referred to as a unit column. Multiple unit rows and multiple unit columns form an array of circuit units arranged in a matrix, and the first direction X intersects with the second direction Y.

As shown in FIG. 5, in an exemplary implementation, the drive circuit layer may further include at least one first power supply line 51 extending along the second direction Y, at least one second power supply line 52 extending along the second direction Y, at least one first power supply connection line 68 extending along the first direction X, and at least one second power supply connection line 69 extending along the first direction X. In an exemplary implementation, a first power supply line 51 is connected to pixel drive circuits in multiple circuit units, and the first power supply line 51 is configured to continuously provide a high-level signal to the pixel drive circuits. A second power supply line 52 is connected to cathodes of multiple light emitting units, and the second power supply line 52 is configured to continuously provide a low-level signal to the cathodes. In an exemplary implementation, the at least one first power supply line 51 extending along the second direction Y and the at least one first power supply connection line 68 extending along the first direction X are interconnected to form a mesh structure for transmitting a first power supply signal, and the at least one second power supply line 52 extending along the second direction Y and the at least one second power supply connection line 69 extending along the first direction X are interconnected to form a mesh structure for transmitting a second power supply signal.

In the present disclosure, A extends along a B direction means that A may include a main portion and a secondary portion connected to the main portion, the main portion is a line, a line segment, or a strip-shaped body, the main portion extends along the B direction, and a length of the main portion extends along the B direction is greater than a length of the secondary portion extends along another direction.

In an exemplary implementation, the drive circuit layer may further include a reference signal connection line 54 and a first reference signal line 91. The first reference signal line 91 may be in a line shape extending along the first direction X, the reference signal connection line 54 may be in a line shape extending along the second direction Y, and the reference signal connection line 54 and the first reference signal line 91 are interconnected to form a mesh structure for transmitting a first reference signal.

In an exemplary implementation, on a plane perpendicular to the display substrate, the drive circuit layer may include a semiconductor layer, a first conductive layer, a second conductive layer, a third conductive layer and a fourth conductive layer that are sequentially provided on the base substrate. A first power supply line 51 and a first power supply connection line 68 may be provided in different conductive layers and the first power supply line 51 and the first power supply connection line 68 may be connected through a via. A second power supply line 52 and a second power supply connection line 69 may be provided in different conductive layers and the second power supply line 52 and the second power supply connection line 69 may be connected through a via.

In an exemplary implementation, the first power supply line 51 and the second power supply line 52 may be provided in a same layer and formed synchronously through a same patterning process, and the first power supply connection line 68 and the second power supply connection line 69 may be provided in a same layer and formed synchronously through a same patterning process.

In an exemplary implementation, the first power supply connection line 68 and the second power supply connection line 69 may be provided in the third conductive layer and the first power supply line 51 and the second power supply line 52 may be provided in the fourth conductive layer.

In an exemplary implementation, the reference signal connection line 54 and the first reference signal line 91 may be provided in different conductive layers and the reference signal connection line 54 and the first reference signal line 91 may be connected through a via.

In an exemplary implementation, the first reference signal line 91 may be provided in the third conductive layer and the reference signal connection line 54 may be provided in the fourth conductive layer.

In an exemplary implementation, at least one circuit unit may include multiple transistors and the semiconductor layer may at least include active layers of the multiple transistors.

In an exemplary implementation, at least one pixel drive circuit may include a first transistor T1 as a first initialization transistor, a second transistor T2 as a compensation transistor, a third transistor T3 as a drive transistor, a fourth transistor T4 as a data writing transistor, a fifth transistor T5 as a first light emitting transistor, a sixth transistor T6 as a second light emitting transistor, a seventh transistor T7 as a second initialization transistor, an eighth transistor T8 as a second reference transistor, a ninth transistor T9 as a first reference transistor, a first storage capacitor and a second storage capacitor.

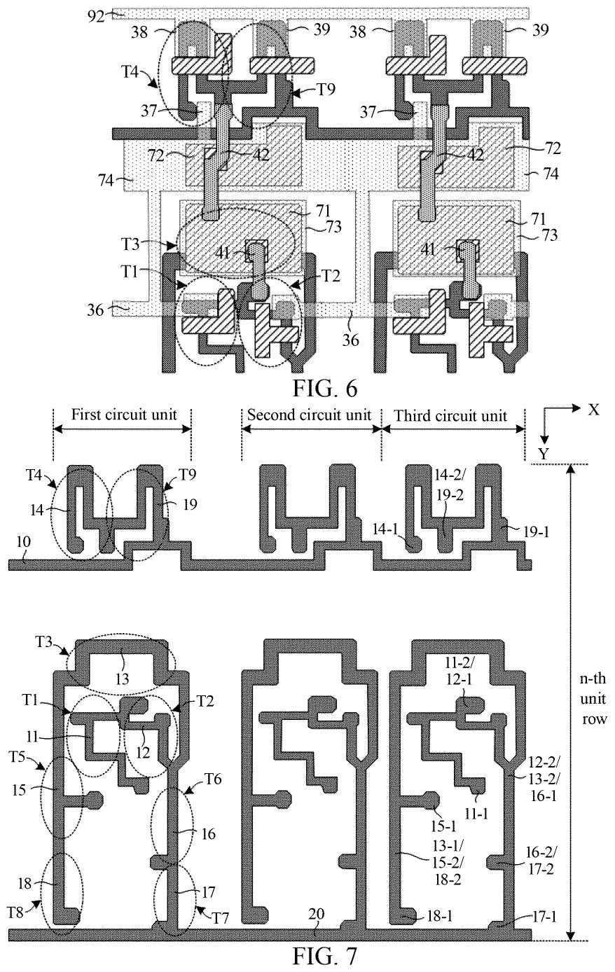

FIG. 6 is an enlarged view of regions of a first storage capacitor and a second storage capacitor in FIG. 5. As shown in FIG. 6, in an exemplary implementation, the first storage capacitor may at least include a first plate 71 and a third plate 73, and an orthographic projection of the third plate 73 on the base substrate is at least partially overlapped with an orthographic projection of the first plate 71 on the base substrate. The second storage capacitor may at least include a second plate 72 and a fourth plate 74, and an orthographic projection of the fourth plate 74 on the base substrate is at least partially overlapped with an orthographic projection of the second plate 72 on the base substrate.

In an exemplary implementation, the first plate 71 and the second plate 72 may be provided in the first conductive layer, and the third plate 73 and the fourth plate 74 may be provided in the second conductive layer. The first plate 71 may serve as a gate electrode of the third transistor T3, the second plate 72 is connected to the third plate 73, and the fourth plate 74 is connected to the first power supply line 51.

In an exemplary implementation, a gate electrode of the first transistor T1 is connected to a fourth scan signal line 64, a first electrode of the first transistor T1 is connected to a first initial signal line 81, and a second electrode of the first transistor T1 is connected to a first electrode of the second transistor T2 and the first plate 71 of the first storage capacitor, respectively. A gate electrode of the second transistor T2 is connected to a second scan signal line 62, and a second electrode of the second transistor T2 is connected to a second electrode of the third transistor T3 and a first electrode of the sixth transistor T6 respectively. The gate electrode of the third transistor T3 serves as the first plate 71 of the first storage capacitor, and a first electrode of the third transistor T3 is connected to a second electrode of the fifth transistor T5 and a second electrode of the eighth transistor T8 respectively. A gate electrode of the fourth transistor T4 is connected to a third scan signal line 63, a first electrode of the fourth transistor T4 is connected to a data signal line 53, and a second electrode of the fourth transistor T4 is connected to a second electrode of the ninth transistor T9, the third plate 73 of the first storage capacitor, and the second plate 72 of the second storage capacitor respectively. A gate electrode of the fifth transistor T5 is connected to a first light emitting signal line 31 and a first electrode of the fifth transistor T5 is connected to the first power supply line 51. A gate electrode of the sixth transistor T6 is connected to a second light emitting signal line 32 and a second electrode of the sixth transistor T6 is connected to a second electrode of the seventh transistor T7. A gate electrode of the seventh transistor T7 is connected to a first scan signal line 61 and a first electrode of the seventh transistor T7 is connected to a second initial signal line 82. A gate electrode of the eighth transistor T8 is connected to the first scan signal line 61 and a first electrode of the eighth transistor T8 is connected to a second reference signal line 92. A gate electrode of the ninth transistor T9 is connected to the second scan signal line 62 and a first electrode of the ninth transistor T9 is connected to the first reference signal line 91.

In an exemplary implementation, the second scan signal line 62 and the fifth scan signal line 65 transmit a same scan signal.

In an exemplary implementation, the first scan signal line 61, the second scan signal line 62, the third scan signal line 63, the fourth scan signal line 64, the fifth scan signal line 65, the first light emitting signal line 31, the second light emitting signal line 32, the first initial signal line 81, the second initial signal line 82, the first reference signal line 91, and the second reference signal line 92 may be in line shapes whose main body portions extend along the first direction X, and the first power supply line 51 and the data signal line 53 may be in line shapes whose main body portions extend along the second direction Y.

In an exemplary implementation, at least one circuit unit may further include an anode connection electrode 55. The anode connection electrode 55 is connected on one hand to the second electrode of the sixth transistor T6 and the second electrode of the seventh transistor T7, respectively and on the other hand to an anode of the light emitting unit.

In an exemplary implementation, the drive circuit layer may further include a repair line 33, the repair line 33 may be in a strip shape whose main body portion extends along the first direction X, and an orthographic projection of the repair line 33 on the base substrate is at least partially overlapped with an orthographic projection of the anode connection electrode 55 on the base substrate.

As shown in FIG. 5 and FIG. 6, in an exemplary implementation, at least one circuit unit may further include a first connection electrode 41. The first connection electrode 41 is connected to the second electrode of the first transistor T1, the first electrode of the second transistor T2, and the first plate 71 of the first storage capacitor respectively, and the first connection electrode 41 may serve as the first node of the pixel drive circuit.

In an exemplary implementation, at least one circuit unit may further include a power supply shielding block 51-1. The power supply shielding block 51-1 is connected to the first power supply line 51, and an orthographic projection of the power supply shielding block 51-1 on the base substrate is at least partially overlapped with an orthographic projection of the first connection electrode 41 on the base substrate to shield an influence of other signals in the pixel drive circuit on the first node.

In an exemplary implementation, at least one circuit unit may further include a second connection electrode 42. The second connection electrode 42 is connected to the second electrode of the fourth transistor T4, the second electrode of the ninth transistor T9, the third plate 73 of the first storage capacitor, and the second plate 72 of the second storage capacitor respectively, and the second connection electrode 42 may serve as the fifth node N5 in the pixel drive circuit,

In an exemplary implementation, an orthographic projection of the first power supply line 51 on the base substrate is at least partially overlapped with an orthographic projection of the second connection electrode 42 on the base substrate to shield an influence of other signals in the pixel drive circuit on the fifth node.

In an exemplary implementation, at least one circuit unit may further include a first shielding electrode 36. The first shielding electrode 36 is connected to the fourth plate 74, an orthographic projection of the first shielding electrode 36 on the base substrate is at least partially overlapped with an orthographic projection of a node between two gate electrodes of the first transistor T1 on the base substrate, and the orthographic projection of the first shielding electrode 36 on the base substrate is at least partially overlapped with an orthographic projection of a node between two gate electrodes of the second transistor T2 on the base substrate. In an exemplary implementation, the first shielding electrode 36 is configured to shield an influence of data voltage jump on the first transistor T1 and the second transistor T2, to avoid the data voltage jump from affecting normal operation of the pixel drive circuit, and to improve the display effect.

In an exemplary implementation, at least one circuit unit may further include a second shielding electrode 37. The second shielding electrode 37 is connected to the fourth plate 74, and the second shielding electrode 37 is provided between the first electrode and second electrode of the fourth transistor T4. In an exemplary implementation, the second shielding electrode 37 is configured to shield an influence of the data voltage jump on the fifth node, avoid the data voltage jump from affecting the normal operation of the pixel drive circuit, and improve the display effect.

In an exemplary implementation, the fourth plate 74, the first shielding electrode 36, and the second shielding electrode 37 may be interconnected to form an integral structure.

In an exemplary implementation, at least one circuit unit may further include a third shielding electrode 38. The third shielding electrode 38 is connected to the second reference signal line 92, and an orthographic projection of the third shielding electrode 38 on the base substrate is at least partially overlapped with an orthographic projection of a node between two gate electrodes of the fourth transistor T4 on the base substrate. In an exemplary implementation, the third shielding electrode 38 is configured to shield an influence of the data voltage jump on the fourth transistor T4, avoid the data voltage jump from affecting the normal operation of the pixel drive circuit, and improve the display effect.

In an exemplary implementation, at least one circuit unit may further include a fourth shielding electrode 39. The fourth shielding electrode is connected to the second reference signal line 92, and an orthographic projection of the fourth shielding electrode 39 on the base substrate is at least partially overlapped with an orthographic projection of a node between two gate electrodes of the ninth transistor T9 on the base substrate. In an exemplary implementation, the fourth shielding electrode 39 is configured to shield an influence of the data voltage jump on the ninth transistor T9, avoid the data voltage jump from affecting the normal operation of the pixel driving circuit, and improve the display effect.

Exemplary description is made below through a manufacturing process of a display substrate. A “patterning process” mentioned in the present disclosure includes photoresist coating, mask exposure, development, etching, photoresist stripping, and the like, for a metal material, an inorganic material, or a transparent conductive material, and includes organic material coating, mask exposure, development, and the like, for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are provided in a same layer” in the present disclosure means that A and B are formed simultaneously through a same patterning process, and a “thickness” of a film layer is a dimension of the film layer in a direction perpendicular to a display substrate. In an exemplary implementation of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B.

In an exemplary implementation, taking three circuit units in the n-th unit row as an example, a manufacturing process of the display substrate of this embodiment may include the following operations.

(11) A pattern of a semiconductor layer is formed. In an exemplary implementation, forming the pattern of the semiconductor layer may include: sequentially depositing a first insulation thin film and a semiconductor thin film on a base substrate, and patterning the semiconductor thin film through a patterning process to form a first insulation layer that covers the base substrate and the semiconductor layer provided on the first insulation layer, as shown in FIG. 7.

In an exemplary implementation, the pattern of the semiconductor layer of each circuit unit in the display substrate may at least include a first active layer 11 of a first transistor T1, a second active layer 12 of a second transistor T2, a third active layer 13 of a third transistor T3, a fourth active layer 14 of a fourth transistor T4, a fifth active layer 15 of a fifth transistor T5, a sixth active layer 16 of a sixth transistor T6, a seventh active layer 17 of a seventh transistor T7, an eighth active layer 18 of an eighth transistor T8 and a ninth active layer 19 of a ninth transistor T9, and the first active layer 11 to the third active layer 13 and the fifth active layer 15 to the eighth active layer 18 may be interconnected to form an integral structure, and the fourth active layer 14 and the ninth active layer 19 may be interconnected to form an integral structure.

In an exemplary implementation, the fourth active layer 14 and the ninth active layer 19 of the n-th unit row may be on a side of the third active layer 13 close to the (n−1)-th unit row, i.e., the fourth active layer 14 and the ninth active layer 19 may be on an opposite side of the third active layer 13 of this circuit unit in the second direction Y. The first active layer 11, the second active layer 12, the fifth active layer 15 to the eighth active layer 18 of the n-th unit row may be on a side of the third active layer 13 close to the (n+1)-th unit row, i.e., the first active layer 11, the second active layer 12, the fifth active layer 15 to the eighth active layer 18 may be on a side of the third active layer 13 of this circuit unit in the second direction Y.

In an exemplary implementation, the first active layer 11 may be on a side of the third active layer 13 of this circuit unit in the second direction Y, the fifth active layer 15 may be on a side of the first active layer 11 of this circuit unit in the second direction Y, and the eighth active layer 18 may be on a side of the fifth active layer 15 of this circuit unit in the second direction Y. The second active layer 12 may be on a side of the third active layer 13 of this circuit unit in the second direction Y, the sixth active layer 16 may be on a side of the second active layer 12 of this circuit unit in the second direction Y, and the seventh active layer 17 may be on a side of the sixth active layer 16 of this circuit unit in the second direction Y.

In an exemplary implementation, the first active layer 11, the fourth active layer 14, the fifth active layer 15, and the eighth active layer 18 may be on a side of this circuit unit in the first direction X (such as a side of an opposite direction of the first direction X), and the second active layer 12, the sixth active layer 16, the seventh active layer 17, and the ninth active layer 19 may be on the other side of this circuit unit in the first direction X (such as a side of the first direction X).

In an exemplary implementation, the first active layer 11 and the second active layer 12 may each be in an “L” shape, the third active layer 13 may be in a “C” shape, the fourth active layer 14 and the ninth active layer 19 may each be in an “n” shape, and the fifth active layer 15, the sixth active layer 16, the seventh active layer 17, and the eighth active layer 18 may each be in an “I” shape.

In an exemplary implementation, an active layer of each transistor may include a first region, a second region, and a channel region located between the first region and the second region. In an exemplary implementation, a second region 11-2 of the first active layer and a first region 12-1 of the second active layer may be interconnected, and the second region 11-2 of the first active layer may serve as the first region 12-1 of the second active layer. A first region 13-1 of the third active layer, a second region 15-2 of the fifth active layer, and a second region 18-2 of the eighth active layer may be interconnected, and the first region 13-1 of the third active layer may simultaneously serve as the second region 15-2 of the fifth active layer and the second region 18-2 of the eighth active layer, constituting a second node N2 of the pixel drive circuit. A second region 12-2 of the second active layer, a second region 13-2 of the third active layer, and a first region 16-1 of the sixth active layer may be interconnected, and the second region 13-2 of the third active layer may simultaneously serve as the second region 12-2 of the second active layer and the first region 16-1 of the sixth active layer, constituting a third node N3 of the pixel drive circuit. A second region 14-2 of the fourth active layer and a second region 19-2 of the ninth active layer may be interconnected, and the second region 14-2 of the fourth active layer may serve as the second region 19-2 of the ninth active layer. A second region 16-2 of the sixth active layer and a second region 17-2 of the seventh active layer may be interconnected, and the second region 16-2 of the sixth active layer may serve as the second region 17-2 of the seventh active layer, constituting a fourth node N4 of the pixel drive circuit. A first region 11-1 of the first active layer, a first region 14-1 of the fourth active layer, a first region 15-1 of the fifth active layer, a first region 17-1 of the seventh active layer, a first region 18-1 of the eighth active layer, and a first region 19-1 of the ninth active layer may be provided separately, the first region 14-1 of the fourth active layer may be on a side of a channel region of the fourth active layer close to the third active layer 13, and the first region 19-1 of the ninth active layer may be on a side of a channel region of the ninth active layer close to the third active layer 13.

In an exemplary implementation, in at least one unit row, semiconductor layers in circuit units adjacent in the first direction X are interconnected, i.e. the semiconductor layer of the first circuit unit of the n-th unit row is connected to the semiconductor layer of the second circuit unit of the n-th unit row, and the semiconductor layer of the second circuit unit of the n-th unit row is connected to the semiconductor layer of the third circuit unit of the n-th unit row.

In an exemplary implementation, the display substrate may further include a first active connection line 10 and a second active connection line 20. The first active connection line 10 may be on a side of the ninth active layer 19 in the second direction Y and connected to the first region 19-1 of the ninth active layer of each circuit unit. The second active connection line 20 may be on a side of the seventh active layer 17 in the second direction Y and connected to the first region 17-1 of the seventh active layer of each circuit unit.

In an exemplary implementation, the first active connection line 10 may be in a polyline shape whose main body portion extends along the first direction X, and the first active connection line 10 and the ninth active layers of multiple circuit units may be interconnected to form an integral structure. Since the first regions of the ninth active layers are connected to a first reference signal line to be formed subsequently, the first active connection line 10 may also be used as the first reference signal line extending along the first direction X, which can not only ensure that the first regions of the multiple ninth active layers in one unit row have a same potential, but also reduce a voltage drop of the first reference signal, which is beneficial to improving uniformity of the panel, avoiding poor display of the display substrate, and ensuring the display effect of the display substrate.

In an exemplary implementation, the second active connection line 20 may be in a straight line shape whose main body portion extends along the first direction X, and the second active connection line 20 and the seventh active layers of multiple circuit units may be interconnected to form an integral structure. Since the first regions of the seventh active layers are connected to a second initial signal line to be formed subsequently, the second active connection line 20 may also be used as the second initial signal line extending along the first direction X, which can not only ensure that the first regions of the multiple seventh active layers in one unit row have a same potential, but also reduce a voltage drop of the second initial signal, which is beneficial to improving the uniformity of the panel, avoid the poor display of the display substrate and ensuring the display effect of the display substrate.

In an exemplary implementation, in at least one unit column, the semiconductor layers in circuit units adjacent in the second direction Y are spaced from each other, i.e. the semiconductor layers of the first circuit units of the (n−1)-th unit row are not connected to the semiconductor layers of the first circuit units of the n-th unit row, and the semiconductor layers of the first circuit units of the n-th unit row are not connected to the semiconductor layers of the first circuit units of the (n+1)-th unit row.

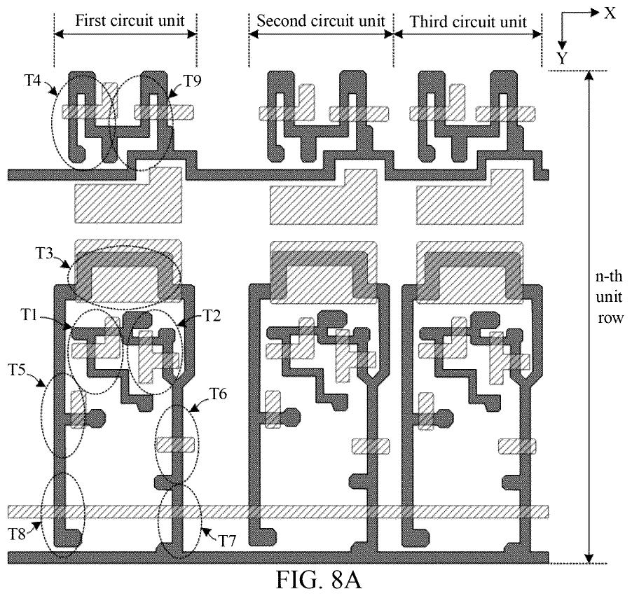

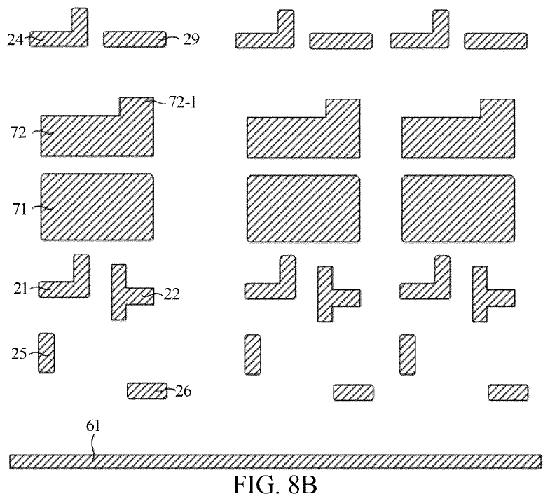

(12) A pattern of a first conductive layer is formed. In an exemplary implementation, forming the pattern of the first conductive layer may include: sequentially depositing a second insulation thin film and a first conductive thin film on the base substrate on which the aforementioned patterns are formed, and patterning the first conductive thin film through a patterning process to form a second insulation layer that covers a pattern of a semiconductor layer and the pattern of the first conductive layer provided on the second insulation layer, as shown in FIG. 8A and FIG. 8B, and FIG. 8B is a schematic diagram of the first conductive layer in FIG. 8A. In an exemplary implementation, the first conductive layer may be referred to as a first gate metal (GATE1) layer.

In an exemplary implementation, the pattern of the first conductive layer of each circuit unit in the display substrate at least includes a first gate electrode 21, a second gate electrode 22, a fourth gate electrode 24, a fifth gate electrode 25, a sixth gate electrode 26, a ninth gate electrode 29, a first scan signal line 61, a first plate 71 of a first storage capacitor, and a second plate 72 of a second storage capacitor.

In an exemplary implementation, the first gate electrode 21 may be in an “L” shape, the first gate electrode 21 may be on a side of the first plate 71 in the second direction Y, and a region where the first gate electrode 21 is overlapped with the first active layer may serve as a gate electrode of the first transistor T1 with a double-gate structure.

In an exemplary implementation, the second gate electrode 22 may be in a “T” shape, the second gate electrode 22 may be on a side of the first plate 71 in the second direction Y, and a region where the second gate electrode 22 is overlapped with the second active layer may serve as a gate electrode of the second transistor T2 with a double-gate structure.

In an exemplary implementation, the fourth gate electrode 24 may be in an “L” shape, the fourth gate electrode 24 may be on a side of the second plate 72 in an opposite direction of the second direction Y, and a region where the fourth gate electrode 24 is overlapped with the fourth active layer may serve as a gate electrode of the fourth transistor T4 with a double-gate structure.

In an exemplary implementation, the fifth gate electrode 25 may be in a strip shape extending along the second direction Y, the fifth gate electrode 25 may be on a side of the first gate electrode 21 in the second direction Y, and a region where the fifth gate electrode 25 is overlapped with the fifth active layer may serve as a gate electrode of the fifth transistor T5.

In an exemplary implementation, the sixth gate electrode 26 may be in a strip shape extending along the first direction X, the sixth gate electrode 26 may be on a side of the second gate electrode 22 in the second direction Y, and a region where the sixth gate electrode 26 is overlapped with the sixth active layer may serve as a gate electrode of the sixth transistor T6.

In an exemplary implementation, the ninth gate electrode 29 may be in a strip shape extending along the first direction X, the ninth gate electrode 29 may be on a side of the second plate 72 in the opposite direction of the second direction Y, and a region where the ninth gate electrode 29 is overlapped with the ninth active layer may serve as a gate electrode of the ninth transistor T9 with a double-gate structure.

In an exemplary implementation, the first scan signal line 61 may be in a line shape whose main body portion extends along the first direction X, the first scan signal line 61 may be on a side of the fifth gate electrode 25 and the sixth gate electrode 26 in the second direction Y, a region where the first scan signal line 61 is overlapped with the seventh active layer may serve as a gate electrode of the seventh transistor T7, and a region where the first scan signal line 61 is overlapped with the eighth active layer may serve as a gate electrode of the eighth transistor T8.

In an exemplary implementation, the first plate 71 of the first storage capacitor may be in a rectangular shape, corners of the rectangular shape may be provided with chamfers, an orthographic projection of the first plate 71 on the base substrate is at least partially overlapped with an orthographic projection of the third active layer of the third transistor T3 on the base substrate, and the first plate 71 may simultaneously serve as a lower plate of the first storage capacitor and a gate electrode of the third transistor T3.

In an exemplary implementation, the second plate 72 of the second storage capacitor may be in a rectangular shape, corners of the rectangular shape may be provided with chamfers, and the second plate 72 of the second storage capacitor may be on a side of the first plate 71 in the opposite direction of the second direction Y and on a side of the fourth gate electrode 24 and the ninth gate electrode 29 in the second direction Y, i.e., the second plate 72 is between the first plate 71 and the fourth gate electrode 24 (the ninth gate electrode 29) in the second direction Y. An orthographic projection of the second plate 72 on the base substrate is not overlapped with an orthographic projection of the semiconductor layer on the base substrate. In an exemplary implementation, the second plate 72 may serve as a lower plate of the second storage capacitor.

In an exemplary implementation, an area of the orthographic projection of the first plate 71 on the base substrate and an area of the orthographic projection of the second plate 72 on the base substrate may be the same, or may be different.

In an exemplary implementation, a region where the first active connection line 10 is connected to the first region of the ninth active layer is bent towards the ninth active layer so that a concave part is formed on a side of the first active connection line 10 away from the ninth active layer. A protrusion part 72-1 is provided on a side of the second plate 72 close to the first active connection line 10, and the protrusion part 72-1 is in a rectangular shape. A first end of the protrusion part 72-1 is connected to the second plate 72, and a second end of the protrusion part 72-1 extends into the concave part of the first active connection line 10.

In an exemplary implementation, the second plate 72 and the protrusion part 72-1 may be interconnected to form an integral structure. By providing the concave part of the first active connection line 10 and the protrusion part 72-1 of the second plate 72, an area of the second plate 72 may be effectively increased and a capacitance of the second storage capacitor may be effectively increased.

In an exemplary implementation, after the pattern of the first conductive layer is formed, a conductive processing may be performed on the semiconductor layer by using the first conductive layer as a shield, the semiconductor layer in a region shielded by the first conductive layer forms channel regions of the first transistor T1 to the ninth transistor T9, and the semiconductor layer in a region not shielded by the first conductive layer is made to be conductive, i.e., first regions and second regions of the first active layer to the ninth active layer are all made to be conductive.

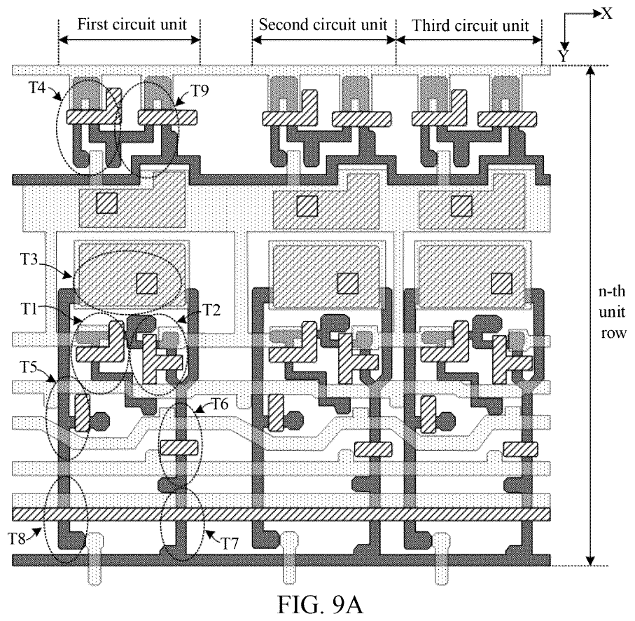

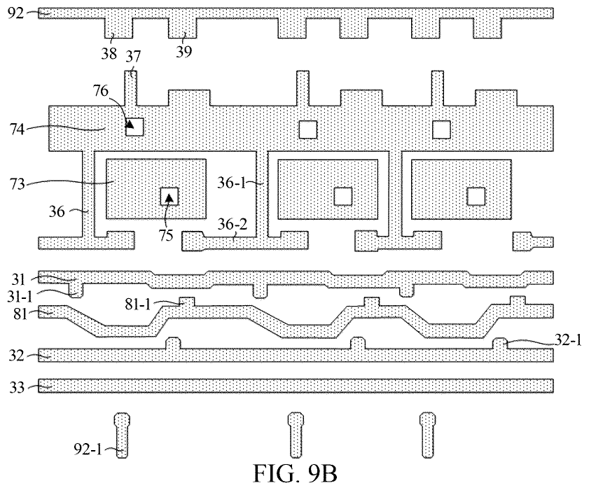

(13) A pattern of a second conductive layer is formed. In an exemplary implementation, forming the pattern of the second conductive layer may include: sequentially depositing a third insulation thin film and a second conductive thin film on the base substrate on which the aforementioned patterns are formed, and the second conductive thin film is patterned through a patterning process to form a third insulation layer that covers the first conductive layer and the pattern of the second conductive layer provided on the third insulation layer, as shown in FIG. 9A and FIG. 9B, and FIG. 9B is a schematic diagram of the second conductive layer in FIG. 9A. In an exemplary implementation, the second conductive layer may be referred to as a second gate metal (GATE2) layer.

In an exemplary implementation, the pattern of the second conductive layer of each circuit unit in the display substrate at least includes: a first light emitting signal line 31, a second light emitting signal line 32, a repair line 33, a first shielding electrode 36, a second shielding electrode 37, a third shielding electrode 38, a fourth shielding electrode 39, a third plate 73 of the first storage capacitor, a fourth plate 74 of the second storage capacitor, a first initial signal line 81, and a second reference signal line 92.

In an exemplary implementation, the first light emitting signal line 31, the second light emitting signal line 32, the repair line 33, the first initial signal line 81, and the second reference signal line 92 may be in line shapes whose main body portions extend along the first direction X, the first light emitting signal line 31, the second light emitting signal line 32, the repair line 33, and the first initial signal line 81 may be between the first gate electrode 21 and the first scan signal line 61, and the second reference signal line 92 may be on a side of the fourth gate electrode 24 in the opposite direction of the second direction Y.

In an exemplary implementation, the first light emitting signal line 31 may be on a side of the first gate electrode 21 of this circuit unit in the second direction Y, the first initial signal line 81 may be on a side of the first light emitting signal line 31 of this circuit unit in the second direction Y, the second light emitting signal line 32 may be on a side of the first initial signal line 81 of this circuit unit in the second direction Y, the repair line 33 may be on a side of the second light emitting signal line 32 of this circuit unit in the second direction Y, i.e., the second light emitting signal line 32 may be between the first light emitting signal line 31 and the repair line 33, the first initial signal line 81 may be between the first light emitting signal line 31 and the second light emitting signal line 32, and the second reference signal line 92 may be on a side of the first light emitting signal line 31 in the opposite direction of the second direction Y.

In an exemplary implementation, a first light emitting connection block 31-1 is provided on a side of the first light emitting signal line 31 close to the second light emitting signal line 32, and the first light emitting connection block 31-1 may be provided in each circuit unit. A first end of the first light emitting connection block 31-1 is connected to the first light emitting signal line 31, a second end of the first light emitting connection block 31-1 extends towards the second light emitting signal line 32, and the first light emitting connection block 31-1 is configured to be connected to the fifth gate electrode 25 through a seventh connection electrode to be formed subsequently. In an exemplary implementation, the first light emitting signal line 31 and multiple first light emitting connection blocks 31-1 may be interconnected to form an integral structure.

In an exemplary implementation, a second light emitting connection block 32-1 is provided on a side of the second light emitting signal line 32 close to the first light emitting signal line 31, and the second light emitting connection block 32-1 may be provided in each circuit unit. A first end of the second light emitting connection block 32-1 is connected to the second light emitting signal line 32, a second end of the second light emitting connection block 32-1 extends towards the first light emitting signal line 31, and the second light emitting connection block 32-1 is configured to be connected to the sixth gate electrode 26 through an eighth connection electrode to be formed subsequently. In an exemplary implementation, the second initial signal line 32 and multiple second light emitting connection blocks 32-1 may be interconnected to form an integral structure.

In an exemplary implementation, a first initial connection block 81-1 is provided on a side of the first initial signal line 81 close to the first light emitting signal line 31, and the first initial connection block 81-1 may be provided in each circuit unit. A first end of the first initial connection block 81-1 is connected to the first initial signal line 81, a second end of the first initial connection block 81-1 extends towards the first light emitting signal line 31, the first initial connection block 81-1 is configured to be connected to the first region of the first active layer through a ninth connection electrode to be formed subsequently, thereby realizing that the first initial signal line 81 is connected to the first electrode of the first transistor T1 and the first initial signal line 81 can write a first initial signal to the first electrode of the first transistor T1. In an exemplary implementation, the first initial signal line 81 and multiple first initial connection blocks 81-1 may be interconnected to form an integral structure.

In an exemplary implementation, a second reference connection block 92-1 is provided on a side of the second reference signal line 92 of the (n+1)-th unit row away from the fourth plate 74 of the (n+1)-th unit row, and the second reference connection block 92-1 may be provided in each circuit unit. A first end of the second reference connection block 92-1 is connected to the second reference signal line 92, and a second end of the second reference connection block 92-1 extends in a direction away from the fourth plate 74, i.e., in a direction towards the n-th unit row. In an exemplary implementation, the second reference connection block 92-1 of the second reference signal line 92 in the (n+1)-th unit row is configured to be connected to the first region of the eighth active layer in the n-th unit row through a sixth connection electrode to be formed subsequently, so as to provide a second reference signal to the first electrode of the eighth transistor T8 in the n-th unit row. In an exemplary implementation, the second reference signal line 92 and multiple second reference connection blocks 92-1 may be interconnected to form an integral structure.

In an exemplary implementation, a contour of the third plate 73 of the first storage capacitor may be in a rectangular shape, corners of the rectangular shape may be provided with chamfers, and the third plate 73 of the first storage capacitor is between the first light emitting signal line 31 and the second reference signal line 92 of this circuit unit. An orthographic projection of the third plate 73 on the base substrate is at least partially overlapped with an orthographic projection of the first plate 71 on the base substrate, the third plate 73 may serve as an upper plate of the first storage capacitor, and the first plate 71 and the second plate 33 constitute the first storage capacitor C1 of the pixel drive circuit.

In an exemplary implementation, a contour of the fourth plate 74 of the second storage capacitor may be in a rectangular shape, corners of the rectangular shape may be provided with chamfers, the fourth plate 74 of the second storage capacitor is between the second reference signal line 92 and the third plate 73 of this circuit unit. An orthographic projection of the fourth plate 74 on the base substrate is at least partially overlapped with an orthographic projection of the second plate 72 on the base substrate, the fourth plate 74 may serve as an upper plate of the second storage capacitor, and the second plate 72 and the fourth plate 74 constitute the second storage capacitor C2 of the pixel drive circuit.

In an exemplary implementation, an area of the orthographic projection of the third plate 73 on the base substrate and an area of the orthographic projection of the fourth plate 74 on the base substrate may be the same, or may be different. For example, the area of the orthographic projection of the fourth plate 74 on the base substrate may be greater than the area of the orthographic projection of the third plate 73 on the base substrate.

In an exemplary implementation, the third plate 73 of each circuit unit is provided with a first opening 75, the first opening 75 may be in the middle of the third plate 73, and the first opening 75 may be rectangular so that the third plate 73 forms an annular structure. The first opening 75 exposes the third insulation layer covering the first plate 71, and the orthographic projection of the first plate 71 on the base substrate contains an orthographic projection of the first opening 75 on the base substrate. In an exemplary implementation, the first opening 75 is configured to accommodate a tenth via to be formed subsequently, and the tenth via is in the first opening 75 and exposes the first plate 71, so that a first connection electrode to be formed subsequently is connected to the first plate 71.

In an exemplary implementation, the fourth plate 74 of each circuit unit is provided with a second opening 76, the second opening 76 may be in the middle of the fourth plate 74, and the second opening 76 may be rectangular so that the fourth plate 74 forms an annular structure. The second opening 76 exposes the third insulation layer covering the second plate 72, and the orthographic projection of the second plate 72 on the base substrate contains an orthographic projection of the second opening 76 on the base substrate. In an exemplary implementation, the second opening 76 is configured to accommodate an eleventh via to be formed subsequently, and the eleventh via is in the second opening 76 and exposes the second plate 72, so that a second connection electrode to be formed subsequently is connected to the second plate 72.

In an exemplary implementation, the first shielding electrode 36 may be in a “T” shape, the first shielding electrode 36 may be on a side of the fourth plate 74 close to the first light emitting signal line 31, and the first shielding electrode 36 may be provided in each circuit unit. The “T” shaped first shielding electrode 36 may include a first extension segment 36-1 and a first shielding segment 36-2. A first end of the first extension segment 36-1 is connected to the fourth plate 74, and a second end of the first extension segment 36-1 is connected to the first shielding segment 36-2 after extending toward the first light emitting signal line 31. The first shielding segment 36-2 may be in a strip shape extending along the first direction X. For a first shielding end of the first shielding segment 36-2 on a side of the first extension segment 36-1 in the first direction X and a second shielding end of the first shielding segment 36-2 on a side of the first extension segment 36-1 in an opposite direction of the first direction X, an orthographic projection of the first shielding end on the base substrate is at least partially overlapped with an orthographic projection of a semiconductor layer between two gate electrodes of the first transistor T1 in this circuit unit on the base substrate. An orthographic projection of the second shielding end on the base substrate is at least partially overlapped with an orthographic projection of a semiconductor layer between two gate electrodes of the second transistor T2 in an adjacent circuit unit on the base substrate. In an exemplary implementation, the first shielding electrode 36 is configured to shield an influence of the data voltage jump on the first transistor T1 and the second transistor T2, avoid the data voltage jump from affecting the normal operation of the pixel drive circuit, and improve the display effect.

In an exemplary implementation, the second shielding electrode 37 may be in an “I” shape, the second shielding electrode 37 may be located on a side of the fourth plate 74 close to the second reference signal line 92, and the second shielding electrode 37 may be provided in each circuit unit. A first end of the second shielding electrode 37 is connected to the fourth plate 74, a second end of the second shielding electrode 37 extends toward the second reference signal line 92, and the second end of the second shielding electrode 37 may be between the first electrode of the fourth transistor T4 and the second electrode of the fourth transistor T4. In an exemplary implementation, the second shielding electrode 37 is configured to shield an influence of the data voltage jump on the fifth node N5, avoid the data voltage jump from affecting the normal operation of the pixel drive circuit, and improve the display effect.

In an exemplary implementation, the fourth plate 74, the first shielding electrode 36, and the second shielding electrode 37 may be interconnected to form an integral structure.

In an exemplary implementation, the third shielding electrode 38 and the fourth shielding electrode 39 may each be in a rectangular shape, the third shielding electrode 38 and the fourth shielding electrode 39 may be on a side of the second reference signal line 92 close to the fourth plate 74, and the third shielding electrode 38 and the fourth shielding electrode 39 may be provided in each circuit unit. A first end of the third shielding electrode 38 is connected to the second reference signal line 92 and a second end of the third shielding electrode 38 extends towards the fourth plate 74. A first end of the fourth shielding electrode 39 is connected to the second reference signal line 92 and a second end of the fourth shielding electrode 39 extends towards the fourth plate 74. An orthographic projection of the third shielding electrode 38 on the base substrate is at least partially overlapped with an orthographic projection of a semiconductor layer between two gate electrodes of the fourth transistor T4 in this circuit unit on the base substrate. An orthographic projection of the fourth shielding electrode 39 on the base substrate is at least partially overlapped with an orthographic projection of a semiconductor layer between two gate electrodes of the ninth transistor T9 in this circuit unit on the base substrate. In an exemplary implementation, the third shielding electrode 38 is configured to shield an influence of the data voltage jump on the fourth transistor T4, and the fourth shielding electrode 39 is configured to shield an influence of the data voltage jump on the ninth transistor T9, so as to avoid the data voltage jump from affecting the normal operation of the pixel drive circuit and improve the display effect.

In an exemplary implementation, the repair line 33, as a preset repair line is configured to repair a failed anode by welding. The repair line 33 is configured to input, when a bright spot defect occurs on the display substrate, a signal to an anode of a sub-pixel where the bright spot defect occurs through the repair line 33 and repair it to a dark spot.

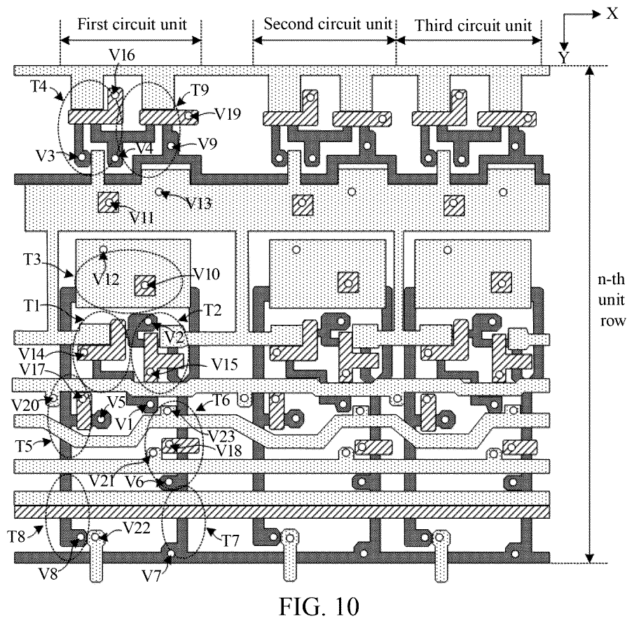

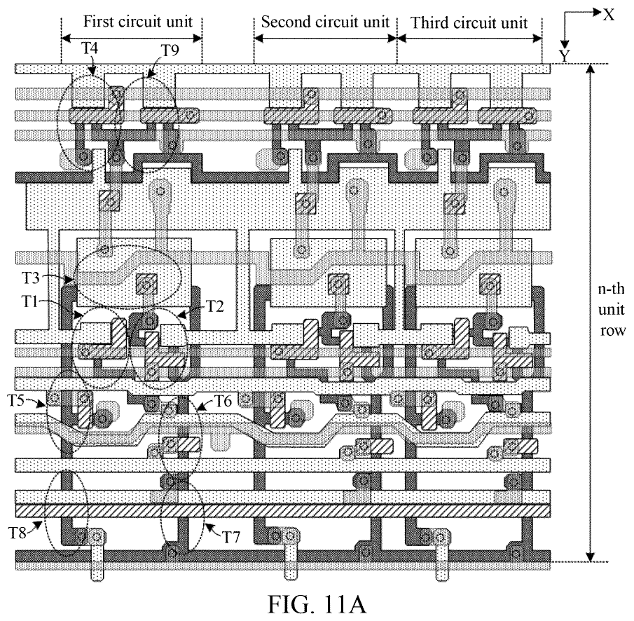

(14) A pattern of a fourth insulation layer is formed. In an exemplary implementation, forming the pattern of the fourth insulation layer may include: depositing a fourth insulation thin film on the base substrate on which the aforementioned patterns are formed, and patterning the fourth insulation thin film through a patterning process, to form the fourth insulation layer that covers the second conductive layer, wherein multiple vias are provided in each circuit unit, as shown in FIG. 10.

In an exemplary implementation, the multiple vias in each circuit unit in the display substrate at least includes a first via V1, a second via V2, a third via V3, a fourth via V4, a fifth via V5, a sixth via V6, a seventh via V7, an eighth via V8, a ninth via V9, a tenth via V10, an eleventh via V11, a twelfth via V12, a thirteenth via V13, a fourteenth via V14, a fifteenth via V15, a sixteenth via V16, a seventeenth via V17, an eighteenth via V18, a nineteenth via V19, a twentieth via V20, a twenty-first via V21, a twenty-second via V22, and a twenty-third via V23.

In an exemplary implementation, an orthographic projection of the first via V1 on the base substrate is within a range of an orthographic projection of the first region of the first active layer on the base substrate, the fourth insulation layer, the third insulation layer, and the second insulation layer in the first via V1 are etched away to expose a surface of the first region of the first active layer, and the first via V1 is configured such that a ninth connection electrode to be formed subsequently is connected to the first region of the first active layer through the first via V1.

In an exemplary implementation, an orthographic projection of the second via V2 on the base substrate is within a range of an orthographic projection of the second region of the first active layer (also the first region of the second active layer) on the base substrate, the fourth insulation layer, the third insulation layer, and the second insulation layer in the second via V2 are etched away to expose a surface of the second region of the first active layer (also the first region of the second active layer), and the second via V2 is configured such that a first connection electrode to be formed subsequently is connected to the second region of the first active layer (also the first region of the second active layer) through the second via V2.

In an exemplary implementation, an orthographic projection of the third via V3 on the base substrate is within a range of an orthographic projection of the first region of the fourth active layer on the base substrate, the fourth insulation layer, the third insulation layer, and the second insulation layer in the third via V3 are etched away to expose a surface of the first region of the fourth active layer, and the third via V3 is configured such that a third connection electrode to be formed subsequently is connected to the first region of the fourth active layer through the third via V3.

In an exemplary implementation, an orthographic projection of the fourth via V4 on the base substrate is within a range of an orthographic projection of the second region of the fourth active layer (also the second region of the ninth active layer) on the base substrate, the fourth insulation layer, the third insulation layer, and the second insulation layer in the fourth via V4 are etched away to expose a surface of the second region of the fourth active layer (also the second region of the ninth active layer), and the fourth via V4 is configured such that a second connection electrode to be formed subsequently is connected to the second region of the fourth active layer (also the second region of the ninth active layer) through the fourth via V4.

In an exemplary implementation, an orthographic projection of the fifth via V5 on the base substrate is within a range of an orthographic projection of the first region of the fifth active layer on the base substrate, the fourth insulation layer, the third insulation layer, and the second insulation layer in the fifth via V5 are etched away to expose a surface of a first region of the fifth active layer, and the fifth via V5 is configured such that a fourth connection electrode to be formed subsequently is connected to the first region of the fifth active layer through the fifth via V5.

In an exemplary implementation, an orthographic projection of the sixth via V6 on the base substrate is within a range of an orthographic projection of the second region of the sixth active layer (also the second region of the seventh active layer) on the base substrate, the fourth insulation layer, the third insulation layer, and the second insulation layer in the sixth via V6 are etched away to expose a surface of the second region of the sixth active layer (also the second region of the seventh active layer), and the sixth via V6 is configured such that a fifth connection electrode to be formed subsequently is connected to the second region of the sixth active layer (also the second region of the seventh active layer) through the sixth via V6.

In an exemplary implementation, an orthographic projection of the seventh via V7 on the base substrate is within a range of an orthographic projection of the first region of the seventh active layer on the base substrate, the fourth insulation layer, the third insulation layer, and the second insulation layer in the seventh via V7 are etched away to expose a surface of the first region of the seventh active layer, and the seventh via V7 is configured such that the second initial signal line to be formed subsequently is connected to the first region of the seventh active layer through the seventh via V7.

In an exemplary implementation, an orthographic projection of the eighth via V8 on the base substrate is within a range of an orthographic projection of the first region of the eighth active layer on the base substrate, the fourth insulation layer, the third insulation layer, and the second insulation layer in the eighth via V8 are etched away to expose a surface of the first region of the first active layer, and the eighth via V8 is configured such that a second connection electrode to be formed subsequently is connected to the first region of the eighth active layer through the eighth via V8.

In an exemplary implementation, an orthographic projection of the ninth via V9 on the base substrate is within a range of an orthographic projection of the first region of the ninth active layer on the base substrate, the fourth insulation layer, the third insulation layer, and the second insulation layer in the ninth via V9 are etched away to expose a surface of the first region of the ninth active layer, and the ninth via V9 is configured such that the first reference signal line to be formed subsequently is connected to the first region of the ninth active layer through the ninth via V9.

In an exemplary implementation, an orthographic projection of the tenth via V10 on the base substrate is within a range of an orthographic projection of the first opening 75 of the third plate 73 on the base substrate, the fourth insulation layer and the third insulation layer in the tenth via V10 are etched away to expose a surface of the first plate 71, and the tenth via V10 is configured such that a first connection electrode to be formed subsequently is connected to the first plate 71 through the tenth via V10.

In an exemplary implementation, an orthographic projection of the eleventh via V11 on the base substrate is within a range of an orthographic projection of the second opening 76 of the fourth plate 74 on the base substrate, the fourth insulation layer and the third insulation layer in the eleventh via V11 are etched away to expose a surface of the second plate 42, and the eleventh via V11 is configured such that a second connection electrode to be formed subsequently is connected to the second plate 42 through the eleventh via V11.

In an exemplary implementation, an orthographic projection of the twelfth via V12 on the base substrate is within a range of the orthographic projection of the third plate 73 on the base substrate, the fourth insulation layer in the twelfth via V12 is etched away to expose a surface of the third plate 73, and the twelfth via V12 is configured such that a second connection electrode to be formed subsequently is connected to the third plate 73 through the twelfth via V12.

In an exemplary implementation, an orthographic projection of the thirteenth via V13 on the base substrate is within a range of the orthographic projection of the fourth plate 74 on the base substrate, the fourth insulation layer in the thirteenth via V13 is etched away to expose a surface of the fourth plate 74, and the thirteenth via V13 is configured such that a first power supply connection electrode to be formed subsequently is connected to fourth plate 74 through the thirteenth via V13.

In an exemplary implementation, an orthographic projection of the fourteenth via V14 on the base substrate is within a range of an orthographic projection of the first gate electrode 21 on the base substrate, the fourth insulation layer and the third insulation layer in the fourteenth via V14 are etched away to expose a surface of the first gate electrode 21, and the fourteenth via V14 is configured such that a fourth scan signal line to be formed subsequently is connected to the first gate electrode 21 through the fourteenth via V14.

In an exemplary implementation, an orthographic projection of the fifteenth via V15 on the base substrate is within a range of an orthographic projection of the second gate electrode 22 on the base substrate, the fourth insulation layer and the third insulation layer in the fifteenth via V15 are etched away to expose a surface of the second gate electrode 22, and the fifteenth via V15 is configured such that a fifth scan signal line to be formed subsequently is connected to the second gate electrode 22 through the fifteenth via V15.

In an exemplary implementation, an orthographic projection of the sixteenth via V16 on the base substrate is within a range of an orthographic projection of the fourth gate electrode 24 on the base substrate, the fourth insulation layer and the third insulation layer in the sixteenth via V16 are etched away to expose a surface of the fourth gate electrode 24, and the sixteenth via V16 is configured such that a third scan signal line to be formed subsequently is connected to the fourth gate electrode 24 through the sixteenth via V16.

In an exemplary implementation, an orthographic projection of the seventeenth via V17 on the base substrate is within a range of an orthographic projection of the fifth gate electrode 25 on the base substrate, the fourth insulation layer and the third insulation layer in the seventeenth via V17 are etched away to expose a surface of the fifth gate electrode 25, and the seventeenth via V17 is configured such that a seventh connection electrode to be formed subsequently is connected to the fifth gate electrode 25 through the seventeenth via V17.

In an exemplary implementation, an orthographic projection of the eighteenth via V18 on the base substrate is within a range of an orthographic projection of the sixth gate electrode 26 on the base substrate, the fourth insulation layer and the third insulation layer in the eighteenth via V18 are etched away to expose a surface of the sixth gate electrode 26, and the eighteenth via V18 is configured such that an eighth connection electrode to be formed subsequently is connected to the sixth gate electrode 26 through the eighteenth via V18.

In an exemplary implementation, an orthographic projection of the nineteenth via V19 on the substrate is within a range of an orthographic projection of the ninth gate electrode 29 on the base substrate, the fourth insulation layer and the third insulation layer in the nineteenth via V19 are etched away to expose a surface of the ninth gate electrode 29, and the nineteenth via V19 is configured such that a second scan signal line to be formed subsequently is connected to the ninth gate electrode 29 through the nineteenth via V19.

In an exemplary implementation, an orthographic projection of the twentieth via V20 on the base substrate is within a range of an orthographic projection of the first light emitting connection block 31-1 of the first light emitting signal line 31 on the base substrate, the fourth insulation layer in the twentieth via V20 is etched away to expose a surface of the first light emitting connection block 31-1, and the twentieth via V20 is configured such that a seventh connection electrode to be formed subsequently is connected to the first light emitting connection block 31-1 through the twentieth via V20.

In an exemplary implementation, an orthographic projection of the twenty-first via V21 on the base substrate is within a range of an orthographic projection of the second light emitting connection block 32-1 of the second light emitting signal line 32 on the base substrate, the fourth insulation layer in the twenty-first via V21 is etched away to expose a surface of the second light emitting connection block 32-1, and the twenty-first via V21 is configured such that an eighth connection electrode to be formed subsequently is connected to the second light emitting connection block 32-1 through the twenty-first via V21.

In an exemplary implementation, an orthographic projection of the twenty-second via V22 on the base substrate is within a range of an orthographic projection of the second reference connection block 92-1 of the second reference signal line 92 on the base substrate, the fourth insulation layer in the twenty-second via V22 is etched away to expose a surface of the second reference connection block 92-1, and the twenty-second via V22 is configured such that a sixth connection electrode to be formed subsequently is connected to the second reference connection block 92-1 through the twenty-second via V22.

In an exemplary implementation, an orthographic projection of the twenty-third via V23 on the base substrate is within a range of an orthographic projection of the first initial connection block 81-1 of the first initial signal line 81 on the base substrate, the fourth insulation layer in the twenty-third via V23 is etched away to expose a surface of the first initial connection block 81-1, and the twenty-third via V23 is configured such that a ninth connection electrode to be formed subsequently is connected to the first initial connection block 81-1 through the twenty-third via V23.

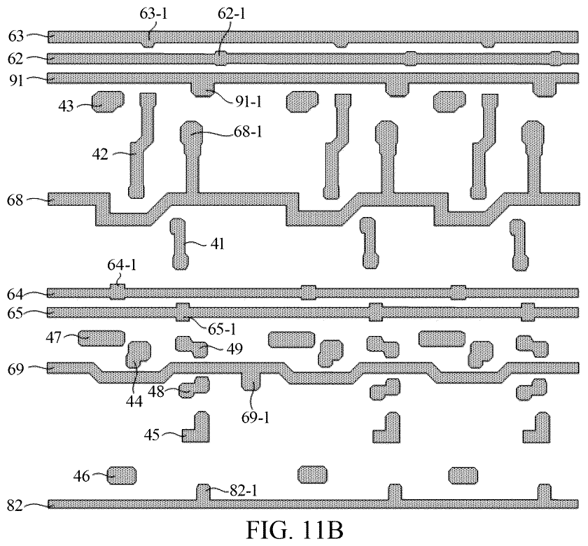

(15) A pattern of a third conductive layer is formed. In an exemplary implementation, forming the pattern of the third conductive layer may include: depositing a third conductive thin film on the base substrate on which the aforementioned patterns are formed, patterning the third conductive thin film through a patterning process to form the third conductive layer provided on the fourth insulation layer, as shown in FIG. 11A and FIG. 11B, and FIG. 11B is a schematic diagram of the third conductive layer in FIG. 11A. In an exemplary implementation, the third conductive layer may be referred to as a first source-drain metal (SD1) layer.

In an exemplary implementation, the pattern of the third conductive layer of each circuit unit in the display substrate may include a first connection electrode 41, a second connection electrode 42, a third connection electrode 43, a fourth connection electrode 44, a fifth connection electrode 45, a sixth connection electrode 46, a seventh connection electrode 47, an eighth connection electrode 48, a ninth connection electrode 49, a second scan signal line 62, a third scan signal line 63, a fourth scan signal line 64, a fifth scan signal line 65, a first power supply connection line 68, a second power supply connection line 69, a second initial signal line 82, and a first reference signal line 91.

In an exemplary implementation, the second scan signal line 62, the third scan signal line 63, the fourth scan signal line 64, the fifth scan signal line 65, the first power supply connection line 68, the second power supply connection line 69, the second initial signal line 82, and the first reference signal line 91 may be in line shapes whose main body portions extend along the first direction X. The second scan signal line 62, the third scan signal line 63, and the first reference signal line 91 may be on a side of the fourth plate 74 in the opposite direction of the second direction Y and the fourth scan signal line 64, the fifth scan signal line 65, and the second initial signal line 82 may be on a side of the third plate 73 in the second direction Y. The first power supply connection line 68 may be in a region where the third plate 73 is located. The second power supply connection line 69 may be between the fifth scan signal line 65 and the second initial signal line 82. The second power supply connection line 69 may be on a side of the first power supply connection line 68 in the second direction Y.

In an exemplary implementation, an orthographic projection of the second power supply connection line 69 on the base substrate is at least partially overlapped with an orthographic projection of the first initial signal line 81 on the base substrate, and the second power supply connection line 69 is configured to be connected to a second power supply line to be formed subsequently to form a low-voltage power supply grid structure with a mesh communication structure on the display substrate. In an exemplary implementation, the first reference signal line 91 may be on a side of the fourth plate 74 in the opposite direction of the second direction Y, the second scan signal line 62 may be on a side of the first reference signal line 91 in the opposite direction of the second direction Y, and the third scan signal line 63 may be on a side of the second scan signal line 62 in the opposite direction of the second direction Y.

In an exemplary implementation, the fourth scan signal line 64 may be on a side of the third plate 73 in the second direction Y, the fifth scan signal line 65 may be on a side of the fourth scan signal line 64 in the second direction Y, the second power supply connection line 69 may be on a side of the fifth scan signal line 65 in the second direction Y, and the second initial signal line 82 may be on a side of the second power supply connection line 69 in the second direction Y.

In an exemplary implementation, the second scan signal line 62 is connected to the ninth gate electrode 29 in each circuit unit through the nineteenth via V19, thereby realizing that the second scan signal line 62 is connected to the ninth gate electrode 29 of the ninth transistor T9, and the second scan signal line 62 can control turned-on and turned-off of the ninth transistor T9.

In an exemplary implementation, the second scan signal line 62 may be provided with a second scan connection block 62-1, and the second scan connection block 62-1 may be in a rectangular shape. The middle of the second scan connection block 62-1 is connected to the second scan signal line 62, a first end of the second scan connection block 62-1 extends toward the first reference signal line 91, and a second end of the second scan connection block 62-1 extends toward the third scan signal line 63. In an exemplary implementation, the second scan connection block 62-1 is configured to be connected to the ninth gate electrode 29 in each circuit unit through the nineteenth via V19, thereby realizing that the second scan signal line 62 is connected to the ninth gate electrode 29 of the ninth transistor T9, and the second scan signal line 62 can control the turn-on and turn-off of the ninth transistor T9.

In the exemplary implementation, the fifth scan signal line 65 is connected to the second gate electrode 22 in each circuit unit through the fifteenth via V15, thereby realizing that the fifth scan signal line 65 is connected to the second gate electrode 22 of the second transistor T2, and the fifth scan signal line 65 can control turned-on and turned-off of the second transistor T2.

In an exemplary implementation, the fifth scan signal line 65 may be provided with a fifth scan connection block 65-1, and the fifth scan connection block 65-1 may be in a rectangular shape. The middle of the fifth scan connection block 65-1 is connected to the fifth scan signal line 65, a first end of the fifth scan connection block 65-1 extends toward the second initial signal line 82, and a second end of the fifth scan connection block 65-1 extends toward the first reference signal line 91. In an exemplary implementation, the fifth scan connection block 65-1 is configured to be connected to the second gate electrode 22 in each circuit unit through the fifteenth via V15, thereby realizing that the fifth scan signal line 65 is connected to the second gate electrode 22 of the second transistor T2, and the fifth scan signal line 65 can control turned-on and turned-off of the second transistor T2.

In an exemplary implementation, the second scan signal line 62 and the fifth scan signal line 65 may be connected to a same gate drive circuit after extending to the bezel area, so as to realize output of the same scan signal, i.e., the second scan signal line 62 and the fifth scan signal line 65 output a same second scan signal.

In an exemplary implementation, the third scan signal line 63 is connected to the fourth gate electrode 24 in each circuit unit through the sixteenth via V16, thereby realizing that the third scan signal line 63 is connected to the fourth gate electrode 24 of the fourth transistor T4, and the third scan signal line 63 can control turned-on and turned-off of the fourth transistor T4.

In an exemplary implementation, a third scan connection block 63-1 is provided on a side of the third scan signal line 63 close to the first reference signal line 91. A first end of the third scan connection block 63-1 is connected to the third scan signal line 63, and a second end of the third scan connection block 63-1 extends towards the first reference signal line 91. In an exemplary implementation, the third scan connection block 63-1 is configured to be connected to the fourth gate electrode 24 in each circuit unit through the sixteenth via V16, thereby realizing that the third scan signal line 63 is connected to the fourth gate electrode 24 of the fourth transistor T4, and the third scan signal line 63 can control turned-on and turned-off of the fourth transistor T4.

In an exemplary implementation, the fourth scan signal line 64 is connected to the first gate electrode 21 in each circuit unit through the fourteenth via V14, thereby realizing that the fourth scan signal line 64 is connected to the first gate electrode 21 of the first transistor T1, and the fourth scan signal line 64 can control turned-on and turned-off of the first transistor T1.

In an exemplary implementation, the fourth scan signal line 64 may be provided with a fourth scan connection block 64-1, and the fourth scan connection block 64-1 may be in a rectangular shape. The middle of the fourth scan connection block 64-1 is connected to the fourth scan signal line 64, a first end of the fourth scan connection block 64-1 extends toward the second initial signal line 82, and a second end of the fourth scan connection block 64-1 extends toward the first reference signal line 91. In an exemplary implementation, the fourth scan connection block 64-1 is configured to be connected to the first gate electrode 21 in each circuit unit through the fourteenth via V14, thereby realizing that the fourth scan signal line 64 is connected to the first gate electrode 21 of the first transistor T1, and the fourth scan signal line 64 can control turned-on and turned-off of the first transistor T1.

In an exemplary implementation, the second initial signal line 82 is connected to the first region of the seventh active layer in each circuit unit through the seventh via V7, thereby realizing that the second initial signal line 82 is connected to the first electrode of the seventh transistor T7, and the second initial signal line 82 can write a second initial signal to the first electrode of the seventh transistor T7.

In an exemplary implementation, a second initial connection block 82-1 is provided on a side of the second initial signal line 82 close to the fifth scan signal line 65. A first end of the second initial connection block 82-1 is connected to the second initial signal line 82, and a second end of the second initial connection block 82-1 extends towards the fifth scan signal line 65. In an exemplary implementation, the second initial connection block 82-1 is configured to be connected to the first region of the seventh active layer in each circuit unit through the seventh via V7, thereby realizing that the second initial signal line 82 is connected to the first electrode of the seventh transistor T7, and the second initial signal line 82 can write the second initial signal to the first electrode of the seventh transistor T7. In an exemplary implementation, since the second active connection line 20 of the semiconductor layer is directly connected to the first regions of the seventh active layers of multiple circuit units in one unit row, and the second initial signal line 82 of the third conductive layer is connected to the first regions of the seventh active layers of multiple circuit units in one unit row through a via, the second active connection line 20 and the second initial signal line 82 constitute a signal line with a double-layer structure, which not only ensures that the first regions of the seventh active layers in one unit row have a same potential, but also reduces resistance of the signal lines, reduces the voltage drop of the second initial signal, which is beneficial to improving the uniformity of the panel, avoiding the poor display of the display substrate, and ensuring the display effect of the display substrate.

In an exemplary implementation, the first reference signal line 91 is connected to the first region of the ninth active layer in each circuit unit through the ninth via V9, thereby realizing that the first reference signal line 91 is connected to the first electrode of the ninth transistor T9, and the first reference signal line 91 can write a first reference signal to the first electrode of the ninth transistor T9.

In an exemplary implementation, a first reference connection block 91-1 is provided on a side of the first reference signal line 91 close to the first power supply connection line 68. A first end of the first reference connection block 91-1 is connected to the first reference signal line 91, a second end of the first reference connection block 91-1 extends towards the first power supply connection line 68, and the first reference connection block 91-1 is configured such that on one hand, the first reference connection block 91-1 is connected to the first region of the ninth active layer through the ninth via V9; on the other hand, the first reference connection block 91-1 is connected to a reference signal connection line to be formed subsequently.

In an exemplary implementation, the first active connection line 10 may be in a polyline shape whose main body portion extends along the first direction X, and the first active connection line 10 and ninth active layers of multiple circuit units may be interconnected to form an integral structure. Since the first regions of the ninth active layers are connected to the first reference signal line to be formed subsequently, the first active connection line 10 may also be used as the first reference signal line extending along the first direction X, which can not only ensure that the first regions of the ninth active layers in one unit row have a same potential, but also reduce the voltage drop of the first reference signal, which is beneficial to improving the uniformity of the panel, avoiding the poor display of the display substrate, and ensuring the display effect of the display substrate.

In an exemplary implementation, the first power supply connection line 68 is connected to the fourth plate 74 in each circuit unit through the thirteenth via V13, thereby realizing that the first power supply connection line 68 is connected to the fourth plate 74. Since the first power supply connection line 68 is connected to a first power supply line to be formed subsequently, the first power supply connection line 68 can write a first power supply signal to the upper plate of the second storage capacitor.

In an exemplary implementation, a first power supply connection block 68-1 is provided on a side of the first power supply connection line 68 away from the second power supply connection line 69. A first end of the first power supply connection block 68-1 is connected to the first power supply connection line 68, and a second end of the first power supply connection block 68-1 extends in a direction away from the second power supply connection line 69. In an exemplary implementation, the first power supply connection block 68-1 is configured such that on one hand, the first power supply connection block 68-1 is connected to the fourth plate 74 through the thirteenth via V13; on the other hand, the first power supply connection block 68-1 is connected to a first power supply line to be formed subsequently.

In an exemplary implementation, an orthographic projection of the first power supply connection line 68 on the base substrate is at least partially overlapped with the orthographic projection of the third plate 73 on the base substrate, and the first power supply connection line 68 is configured such that the first power supply connection line 68 is connected to a first power supply line to be formed subsequently to form a high-voltage power supply grid structure with a mesh communication structure on the display substrate.

In an exemplary implementation, in at least one circuit unit, a second power supply connection block 69-1 is provided on a side of the second power supply connection line 69 away from the first power supply connection line 68. A first end of the second power supply connection block 69-1 is connected to the second power supply connection line 69, a second end of the second power supply connection block 69-1 extends in a direction away from the first power supply connection line 68, and the second power supply connection block 69-1 is configured such that the second power supply connection block 69-1 is connected to a second power supply line to be formed subsequently. In an exemplary implementation, the second power supply connection block 69-1 may be provided between a first circuit unit and a second circuit unit.

In an exemplary implementation, an orthographic projection of the second power supply connection line 69 on the base substrate is at least partially overlapped with the orthographic projection of the first initial signal line 81 on the base substrate, and the second power supply connection line 69 is configured such that the second power supply connection line 69 is connected to a second power supply line to be formed subsequently to form a low-voltage power supply grid structure with a mesh communication structure on the display substrate.

In an exemplary implementation, the first connection electrode 41 may be in a strip shape whose main body portion extends along the second direction Y, and the first connection electrode 41 may be between the fourth scan signal line 64 and the first power supply connection line 68. A first end of the first connection electrode 41 is connected to the second region of the first active layer (also the first region of the second active layer) through the second via V2, and a second end of the first connection electrode 41 is connected to the first plate 71 through the tenth via V10. In an exemplary implementation, the first connection electrode 41 enables the second electrode of the first transistor T1, the first electrode of the second transistor T2, the gate electrode of the third transistor T3 and the first plate 71 of the first storage capacitor (i.e., the first end of the first storage capacitor) to have a same potential, and the first connection electrode 41 may serve as the first node N1 of the pixel drive circuit.

In an exemplary implementation, the second connection electrode 42 may be in a polyline shape whose main body portion extends along the second direction Y, and the second connection electrode 42 may be between the first reference signal line 91 and the first power supply connection line 68. A first end of the second connection electrode 42 is connected to the second region of the fourth active layer (also the second region of the ninth active layer) through the fourth via V4, a second end of the second connection electrode 42 is connected to the third plate 73 through the twelfth via V12, and a third end of the second connection electrode 42 between the first end and the second end is connected to the second plate 72 through the eleventh via V11. In an exemplary implementation, the second connection electrode 42 enables the second electrode of the fourth transistor T4, the second electrode of the ninth transistor T9, the third plate 73 of the first storage capacitor (i.e. the second end of the first storage capacitor) and the second plate 72 of the second storage capacitor (i.e. the second end of the second storage capacitor) to have a same potential, and the second connection electrode 42 may serve as the fifth node N5 of the pixel drive circuit.

In an exemplary implementation, the third connection electrode 43 may be in a rectangular shape, the third connection electrode 43 may be between the first reference signal line 91 and the first power supply connection line 68, and the third connection electrode 43 is connected to the first region of the fourth active layer through the third via V3. In an exemplary implementation, the third connection electrode 43 may serve as the first electrode of the fourth transistor T4, and is configured to be connected to a data signal line to be formed subsequently.

In an exemplary implementation, the fourth connection electrode 44 may be in a rectangular shape, the fourth connection electrode 44 may be between the fifth scan signal line 65 and the second initial signal line 82, and the fourth connection electrode 44 is connected to the first region of the fifth active layer through the fifth via V5. In an exemplary implementation, the fifth connection electrode 44 may serve as the first electrode of the fifth transistor T5, and the fifth connection electrode 44 is configured to be connected to a first power supply line to be formed subsequently.

In an exemplary implementation, the fifth connection electrode 45 may be in an “L” shape, the fifth connection electrode 45 may be between the fifth scan signal line 65 and the second initial signal line 82, and the fifth connection electrode 45 is connected to the second region of the sixth active layer (also the second region of the seventh active layer) through the sixth via V6. In an exemplary implementation, the fifth connection electrode 45 may serve as the second electrode of the sixth transistor T6 and the second electrode of the seventh transistor T7, and the fifth connection electrode 45 is configured to be connected to an anode connection electrode to be formed subsequently.

In an exemplary implementation, the sixth connection electrode 46 may be in a strip shape whose main body portion extends along the first direction X, and the sixth connection electrode 46 may be between the fifth scan signal line 65 and the second initial signal line 82. A first end of the sixth connection electrode 46 is connected to the first region of the eighth active layer through the eighth via V8, and a second end of the sixth connection electrode 46 is connected to the second reference connection block 92-1 through the twenty-second via V22. In an exemplary implementation, the sixth connection electrode 46 may serve as the first electrode of the eighth transistor T8, the second reference connection block 92-1 is connected to the second reference signal line 92, thereby realizing that the second reference signal line 92 is connected to the first electrode of the eighth transistor T8, and the second reference signal line 92 in the n-th unit row may write a second reference signal to the first electrode of the eighth transistor T8 in the (n−1)-th unit row.

In an exemplary implementation, the seventh connection electrode 47 may be in a strip shape whose main body portion extends along the first direction X, and the seventh connection electrode 47 may be between the fifth scan signal line 65 and the second initial signal line 82. A first end of the seventh connection electrode 47 is connected to the fifth gate electrode 25 through the seventeenth via V17, and a second end of the seventh connection electrode 47 is connected to the first light emitting connection block 31-1 through the twentieth via V20. The first light emitting connection block 31-1 is connected to the first light emitting signal line 31, thereby realizing that the first light emitting signal line 31 is connected to the fifth gate electrode 25 of the fifth transistor T5, and the first light emitting signal line 31 can control turn-on and turn-off of the fifth transistor T5.

In an exemplary implementation, the eighth connection electrode 48 may be in a strip shape whose main body portion extends along the first direction X, and the eighth connection electrode 48 may be between the fifth scan signal line 65 and the second initial signal line 82. A first end of the eighth connection electrode 48 is connected to the sixth gate electrode 26 through the eighteenth via V18, and a second end of the eighth connection electrode 48 is connected to the second light emitting connection block 32-1 through the twenty-first via V21. The second light emitting connection block 32-1 is connected to the second light emitting signal line 32, thereby realizing that the second light emitting signal line 32 is connected to the sixth gate electrode 26 of the sixth transistor T6, and the second light emitting signal line 32 can control turn-on and turn-off of the sixth transistor T6.

In an exemplary implementation, the ninth connection electrode 49 may be in a strip shape whose main body portion extends along the first direction X, and the ninth connection electrode 49 may be between the fifth scan signal line 65 and the second initial signal line 82. A first end of the ninth connection electrode 49 is connected to the first region of the first active layer through the first via V1, and a second end of the ninth connection electrode 49 is connected to the first initial connection block 81-1 through the twenty-third via V23. The first initial connection block 81-1 is connected to the first initial signal line 81, thereby realizing that the first initial signal line 81 is connected to the first electrode of the first transistor T1, and the first initial signal line 81 can write a first initial signal to the first electrode of the first transistor T1.

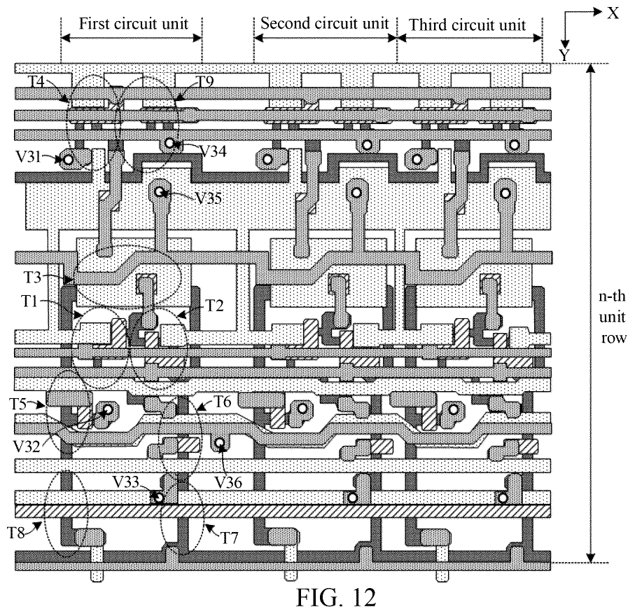

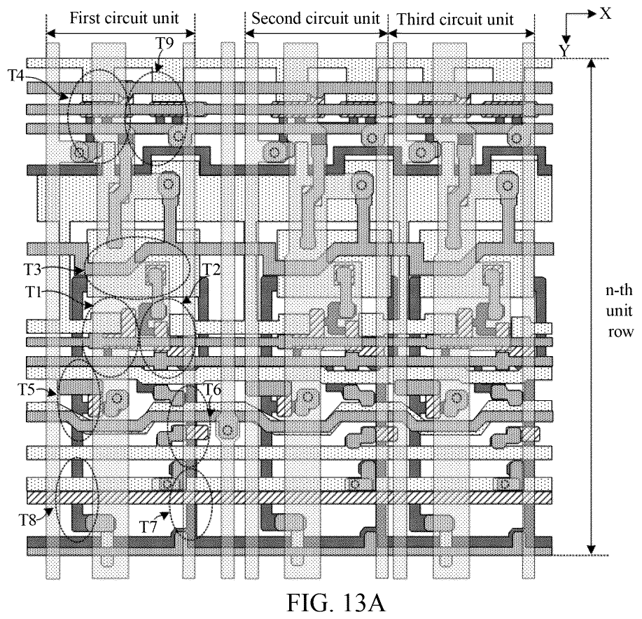

(16) A pattern of a fifth insulation layer is formed. In an exemplary implementation, forming the pattern of the fifth insulation layer may include: depositing a fifth insulation thin film on the base substrate on which the aforementioned patterns are formed, patterning the fifth insulation thin film through a patterning process to form a fifth insulation layer that covers the third conductive layer, wherein multiple vias are provided on each circuit unit, as shown in FIG. 12.

In an exemplary implementation, the multiple vias of each circuit unit in the display substrate at least includes a thirty-first via V31, a thirty-second via V32, a thirty-third via V33, a thirty-fourth via V34, and a thirty-fifth via V35.

In an exemplary implementation, an orthographic projection of the thirty-first via V31 on the base substrate is within a range of an orthographic projection of the third connection electrode 43 on the base substrate, the fifth insulation layer in the thirty-first via V31 is removed to expose a surface of the third connection electrode 43, and the thirty-first via V31 is configured such that a data signal line formed subsequently is connected to the third connection electrode 43 through the thirty-first via V31.

In an exemplary implementation, an orthographic projection of the thirty-second via V32 on the base substrate is within a range of an orthographic projection of the fourth connection electrode 44 on the base substrate, the fifth insulation layer in the thirty-second via V32 is removed to expose a surface of the fourth connection electrode 44, and the thirty-second via V32 is configured such that a power supply line to be formed subsequently is connected to the fourth connection electrode 44 through the thirty-second via V32.

In an exemplary implementation, an orthographic projection of the thirty-third via V33 on the base substrate is within a range of an orthographic projection of the fifth connection electrode 45 on the base substrate, the fifth insulation layer in the thirty-third via V33 is removed to expose a surface of the fifth connection electrode 45, and the thirty-third via V33 is configured such that an anode connection electrode to be formed subsequently is connected to the fifth connection electrode 45 through the thirty-third via V33.

In an exemplary implementation, an orthographic projection of the thirty-fourth via V34 on the base substrate is within a range of an orthographic projection of the first reference connection block 91-1 of the first reference signal line 91 on the base substrate, the fifth insulation layer in the thirty-fourth via V34 is removed to expose a surface of the first reference connection block 91-1, and the thirty-fourth via V34 is configured such that a reference signal connection line to be formed subsequently is connected to the first reference connection block 91-1 through the thirty-fourth via V34.

In an exemplary implementation, an orthographic projection of the thirty-fifth via V35 on the base substrate is within a range of an orthographic projection of the first power supply connection block 68-1 of the first power supply connection line 68 on the base substrate, the fifth insulation layer in the thirty-fifth via V35 is removed to expose a surface of the first power supply connection block 68-1, and the thirty-fifth via V35 is configured such that a first power supply line to be formed subsequently is connected to the first power supply connection block 68-1 through the thirty-fifth via V35.

In an exemplary implementation, a thirty-sixth via V36 may further be included in at least one circuit unit. An orthographic projection of the thirty-sixth via V36 on the base substrate is within a range of an orthographic projection of the second power supply connection block 69-1 of the second power supply connection line 69 on the base substrate. The fifth insulation layer in the thirty-sixth via V36 is removed to expose a surface of the second power supply connection block 69-1. The thirty-sixth via V36 is configured such that a second power supply line to be formed subsequently is connected to the second power supply connection block 69-1 through the thirty-sixth via V36. In an exemplary implementation, the thirty-sixth via V36 may be between a first circuit unit and a second circuit unit.

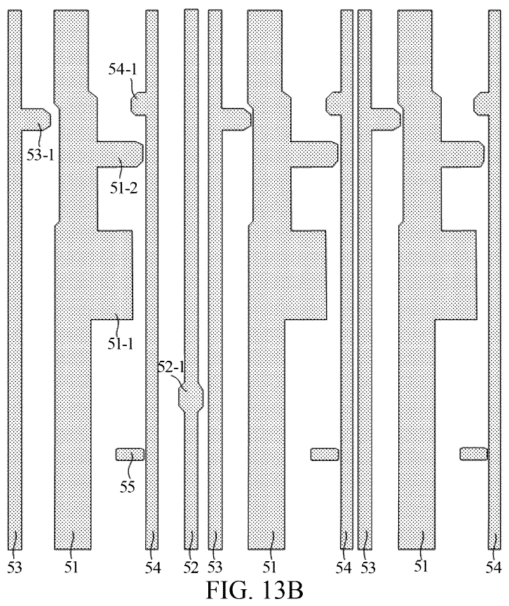

(17) A pattern of a fourth conductive layer is formed. In an exemplary implementation, forming the pattern of the fourth conductive layer may include: depositing a fourth conductive thin film on the base substrate on which the aforementioned patterns are formed, patterning the fourth conductive thin film through a patterning process to form the fourth conductive layer provided on the fifth insulation layer, as shown in FIG. 13A and FIG. 13B, and FIG. 13B is a schematic diagram of the fourth conductive layer in FIG. 13A. In an exemplary implementation, the fourth conductive layer may be referred to as a second source-drain metal (SD2) layer.

In an exemplary implementation, the pattern of the fourth conductive layer of each circuit unit in the display substrate may include a first power supply line 51, a data signal line 53, a reference signal connection line 54, and an anode connection electrode 55.

In an exemplary implementation, shapes of the first power supply line 51, the data signal line 53, and the reference signal connection line 54 may be in strip shapes whose main body portions extend along the second direction Y, the first power supply line 51 may be on a side of the data signal line 53 in the first direction X, and the reference signal connection line 54 may be on a side of the first power supply line 51 in the first direction X, i.e., the first power supply line 51 may be between the data signal line 53 and the reference signal connection line 54.

In an exemplary implementation, the first power supply line 51 may be in a polyline shape whose main body portion extends along the second direction Y. On one hand, the first power supply line 51 is connected to the fourth connection electrode 44 through the thirty-second via V32; on the other hand, the first power supply line 51 is connected to the first power supply connection block 68-1 through the thirty-fifth via V35. The fourth connection electrode 44 is connected to the first region of the fifth active layer through a via, thereby realizing that a first power supply signal is written to the first electrode of the fifth transistor T5 through the first power supply line 51. The first power supply connection block 68-1 is connected to the first power supply connection line 68, thereby realizing that the first power supply connection line 68, whose main body portion extends along the first direction X, and the first power supply line 51, whose main body portion extends along the second direction Y, are interconnected, so that the first power supply line 51 and the first power supply connection line 68 form a mesh structure for transmitting the first power supply signal on the display substrate, which can not only effectively reduce a resistance of the first power supply line 51 and reduce a voltage drop of the first power supply signal, but also effectively improve uniformity of the first power supply signal in the display substrate and effectively improve the display effect and the display quality.

In an exemplary implementation, a power supply shielding block 51-1 is provided on a side of the first power supply line 51 close to the reference signal connection line 54. A first end of the power supply shielding block 51-1 is connected to the first power supply line 51, and a second end of the power supply shielding block 51-1 extends towards the reference signal connection line 54. The power supply shielding block 51-1 may be in a rectangular shape, and an orthographic projection of the power supply shielding block 51-1 on the base substrate is at least partially overlapped with an orthographic projection of the first connection electrode 41 on the base substrate. Since the first connection electrode 41 serves as the first node N1 in the pixel drive circuit, the power supply shielding block 51-1 with a constant voltage can effectively shield influence of other signals in the pixel drive circuit on the first Node N1, thereby avoiding other signals (such as data voltage jump) from affecting the potential of the first node N1 in the pixel drive circuit and improving the display effect.

In an exemplary implementation, the first power supply line 51 and the power supply shielding block 51-1 may be interconnected to form an integral structure.

In an exemplary implementation, the orthographic projection of the power supply shielding block 51-1 on the base substrate may include the orthographic projection of the first connection electrode 41 on the base substrate.

In an exemplary implementation, a third power supply connection block 51-2 is provided on a side of the first power supply line 51 close to the reference signal connection line 54. The third power supply connection block 51-2 may be in a strip shape extending along the first direction X, a first end of the third power supply connection block 51-2 is connected to the first power supply line 51, and a second end of the third power supply connection block 51-2 extends towards the reference signal connection line 54, and is connected to the first power supply connection block 68-1 through the thirty-fifth via V35.

In an exemplary implementation, the first power supply line 51 and the third power supply connection block 51-2 may be interconnected to form an integral structure.

In an exemplary implementation, an orthographic projection of the first power supply line 51 on the base substrate is at least partially overlapped with an orthographic projection of the second connection electrode 42 on the base substrate. Since the second connection electrode 42 serves as the fifth node N5 in the pixel drive circuit, the first power supply line 51 with a constant voltage can effectively shield influence of other signals in the pixel drive circuit on the fifth node N5, avoid the influence of other signals on the potential of the fifth node N5 in the pixel drive circuit, and improve the display effect.

In an exemplary implementation, the first power supply line 51 may be of an unequal-width design, and the first power supply line 51 employing the unequal width design can not only facilitate a layout of a pixel structure, but also reduce a parasitic capacitance between the first power supply line and a data signal line.

In an exemplary implementation, the data signal line 53 may be in a straight line shape whose main body portion extends along the second direction Y, and the data signal line 53 is connected to the third connection electrode 43 through the thirty-first via V31. The third connection electrode 43 is connected to the first region of the fourth active layer through a via, thereby the data signal line 53 writes a data signal to the first electrode of the fourth transistor T4.

In an exemplary implementation, a data signal connection block 53-1 is provide on a side of the data signal line 53 close to the first power supply line 51. A first end of the data signal connection block 53-1 is connected to the data signal line 53, and a second end of the data signal connection block 53-1 extends towards the first power supply line 51. The data signal connection block 53-1 may be in a rectangular shape. The data signal connection block 53-1 is configured to be connected to the third connection electrode 43 through the thirty-first via V31.

In an exemplary implementation, the reference signal connection line 54 may be in a straight line shape whose main body portion extends along the second direction Y, and the reference signal connection line 54 is connected to the first reference connection block 91-1 through the thirty-fourth via V34. The first reference connection block 91-1 is connected to the first reference signal line 91, thereby realizing that the first reference signal line 91, whose main body portion extends along the first direction X, and the reference signal connection line 54, whose main body portion extends along the second direction Y, are interconnected, so that the first reference signal line 91 and the reference signal connection line 54 form a mesh structure for transmitting a first reference signal on the display substrate, which can not only effectively reduce a resistance of the first reference signal line and reduce the voltage drop of the first reference signal, but also effectively improve the uniformity of the first reference signal in the display substrate, effectively improve the display effect and the display quality.

In an exemplary implementation, a reference signal connection block 54-1 is provided on a side of the reference signal connection line 54 close to the data signal line 53. A first end of the reference signal connection block 54-1 is connected to the reference signal connection line 54, and a second end of the reference signal connection block 54-1 extends towards the data signal line 53. The reference signal connection block 54-1 may be in a rectangular shape. The reference signal connection block 54-1 is configured to be connected to the first reference connection block 91-1 through the thirty-fourth via V34.

In an exemplary implementation, the anode connection electrode 55 may be in a rectangular shape, and the anode connection electrode 55 is connected to the fifth connection electrode 45 through the thirty-third via V33. The fifth connection electrode 45 is connected to the second region of the sixth active layer (also the second region of the seventh active layer) through a via, thereby realizing that the anode connection electrode 55 is connected to the second electrode of the sixth transistor T6 and the second electrode of the seventh transistor T7. In an exemplary implementation, the anode connection electrode 55 is configured to be connected to an anode to be formed subsequently, thereby the pixel drive circuit can drive a light emitting device.

In an exemplary implementation, an orthographic projection of the anode connection electrode 55 on the base substrate is at least partially overlapped with an orthographic projection of the repair line 33 on the base substrate.

In an exemplary implementation, a second power supply line 52 may further be included in at least one circuit unit. The second power supply line 52 may be in a straight line shape whose main body portion extends along the second direction Y, and the second power supply line 52 is connected to the second power supply connection block 69-1 through the thirty-sixth via V36. The second power supply connection block 69-1 is connected to the second power supply connection line 69, thereby realizing that the second power supply connection line 69, whose main body portion extends along the first direction X, and the second power supply line 52, whose main body portion extends along the second direction Y are interconnected, so that the second power supply line 52 and the second power supply connection line 69 form a mesh structure for transmitting a second power supply signal on the display substrate, which can not only effectively reduce a resistance of the second power supply line 52 and reduce a voltage drop of the second power supply signal, but also effectively improve uniformity of the second power supply signal in the display substrate, effectively improve the display effect and the display quality.

In an exemplary implementation, the second power supply line 52 may be between the reference signal connection line 54 of the first circuit unit and the data signal line 53 of the second circuit unit.

In an exemplary implementation, the second power supply line 52 is provided with a fourth power supply connection block 52-1, and the middle of the fourth power supply connection block 52-1 is connected to the second power supply line 52. A first end of the fourth power supply connection block 52-1 extends towards the reference signal connection line 54 of the first circuit unit, and a second end of the fourth power supply connection block 52-1 extends towards the data signal line 53 of the second circuit unit. The fourth power supply connection block 52-1 may be in a rectangular shape. In an exemplary implementation, the fourth power supply connection block 52-1 is configured to be connected to the second power supply connection block 69-1 through the thirty-sixth via V36.

In an exemplary implementation, a first power supply connection line 68 of the third conductive layer may be provided in each unit row, and a first power supply line 51 of the fourth conductive layer may be provided in each unit column, and multiple first power supply lines 51 are respectively connected to multiple first power supply connection lines 68 to form a mesh structure for transmitting a first power supply signal.

In an exemplary implementation, a first reference signal line 91 of the third conductive layer may be provided in each unit row, a reference signal connection line 54 of the fourth conductive layer may be provided in each unit column, and multiple first reference signal lines 91 are respectively connected to multiple reference signal connection lines 54 to form a mesh structure for transmitting a first reference signal.

In an exemplary implementation, a second power supply connection line 69 of the third conductive layer may be provided in each unit row, and a second power supply line 52 of the fourth conductive layer may be provided for every three unit columns, and multiple second power supply lines 52 are respectively connected to multiple second power supply connection lines 69 to form a mesh structure for transmitting a second power supply signal.

The subsequent manufacturing process may include forming a pattern of a first planarization layer. Multiple anode vias are provided in the first planarization layer, an orthographic projection of an anode via on the base substrate is within a range of an orthographic projection of an anode connection electrode on the base substrate. A first planarization layer in the anode via is removed to expose a surface of the anode connection electrode, and the anode via is configured to connect an anode to be formed subsequently to the anode connection electrode through the anode via.

At this point, the drive circuit layer of this embodiment is manufactured on the base substrate. In an exemplary implementation, after manufacturing of the drive circuit layer is completed, a light emitting structure layer and an encapsulation structure layer may be sequentially manufactured on the drive circuit layer, which will not be repeated herein.

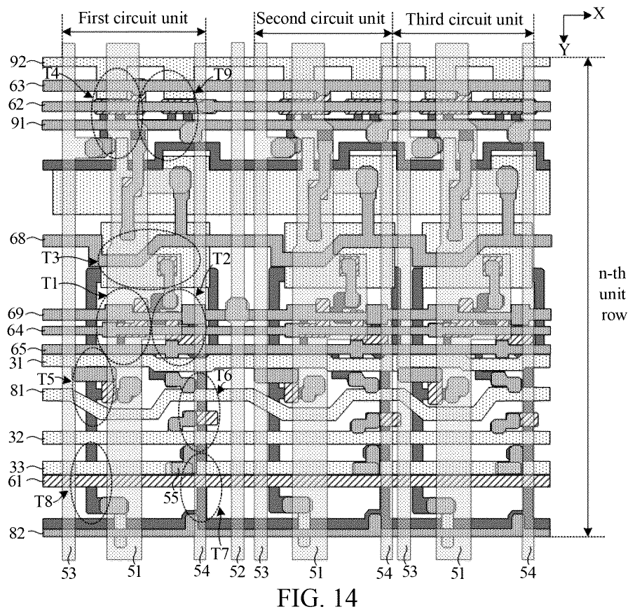

FIG. 14 is a schematic diagram of a planar structure of another display substrate according to an exemplary embodiment of the present disclosure, illustrating a structure of pixel drive circuits in three circuit units (a first circuit unit, a second circuit unit, and a third circuit unit) in the display substrate. As shown in FIG. 14, a main structure of the pixel drive circuits of this exemplary embodiment is substantially the same as a main structure of the foregoing embodiment, except that the second power supply connection line 69 of this embodiment is between the first power supply connection line 68 and the fourth scan signal line 64, and the first shielding electrode 36 and the second power supply connection line 69 are interconnected to form an integral structure.

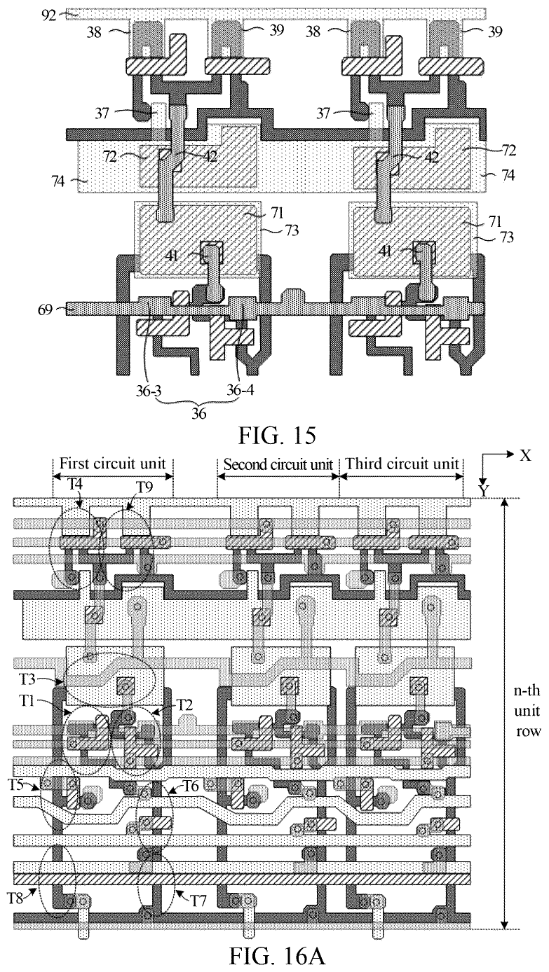

FIG. 15 is an enlarged view of regions of a first storage capacitor and a second storage capacitor in FIG. 14. As shown in FIG. 15, at least one circuit unit may further include a first shielding electrode 36, and the first shielding electrode 36 is connected to the second power supply connection line 69. An orthographic projection of the first shielding electrode 36 on the base substrate is at least partially overlapped with an orthographic projection of a node between two gate electrodes of the first transistor T1 on the base substrate, and the orthographic projection of the first shielding electrode 36 on the base substrate is at least partially overlapped with an orthographic projection of a node between two gate electrodes of the second transistor T2 on the base substrate. In an exemplary implementation, the first shielding electrode 36 is configured to shield an influence of data voltage jump on the first transistor T1 and the second transistor T2, avoid the data voltage jump from affecting the normal operation of the pixel drive circuit, and improve the display effect.

In an exemplary implementation, the first shielding electrode 36 may include a first sub-electrode 36-3 and a second sub-electrode 36-4. A first end of the first sub-electrode 36-3 is connected to the second power supply connection line 69, and a second end of the first sub-electrode 36-3 extends in a direction away from the second power supply connection line 69, i.e., in the opposite direction of the second direction Y. An orthographic projection of the second end of the first sub-electrode 36-3 on the base substrate is at least partially overlapped with an orthographic projection of the node between two gate electrodes of the first transistor T1 in this circuit unit on the base substrate. A first end of the second sub-electrode 36-4 is connected to the second power supply connection line 69, and a second end of the second sub-electrode 36-4 extends in a direction away from the second power supply connection line 69. An orthographic projection of the second end of the second sub-electrode 36-4 on the base substrate is at least partially overlapped with an orthographic projection of the node between two gate electrodes of the second transistor T2 in this circuit unit on the base substrate.

In some possible exemplary implementation, the middle of the first sub-electrode 36-3 is connected to the second power supply connection line 69, a first end of the first sub-electrode 36-3 extends in the opposite direction of the second direction Y, and a second end of the first sub-electrode 36-3 extends in the second direction Y. An orthographic projection of the first end and the second end of the first sub-electrode 36-3 on the base substrate is at least partially overlapped with the orthographic projection of the node between the two gate electrodes of the first transistor T1 in this circuit unit on the base substrate.

In some possible exemplary implementations, the middle of the second sub-electrode 36-4 is connected to the second power supply connection line 69, a first end of the second sub-electrode 36-4 extends in the opposite direction of the second direction Y, and a second end of the second sub-electrode 36-4 extends in the second direction Y. An orthographic projection of the first end and the second end of the second sub-electrode 36-4 on the base substrate is at least partially overlapped with the orthographic projection of the node between the two gate electrodes of the second transistor T2 in this circuit unit on the base substrate.

In an exemplary implementation, the first shielding electrode 36 and the second power supply connection line 69 are interconnected to form an integral structure.

In an exemplary implementation, at least one circuit unit may further include a second shielding electrode 37, a third shielding electrode 38, and a fourth shielding electrode 39, shapes, positions, and connection structures of the second shielding electrode 37, the third shielding electrode 38, and the fourth shielding electrode 39 are substantially the same as those of the foregoing embodiments.

Exemplary description is made below through a manufacturing process of a display substrate. In an exemplary implementation, taking three circuit units in the n-th unit row as an example the manufacturing process of the display substrate of this embodiment may include the following operations.

(21) Patterns of a first insulation layer, a semiconductor layer, a second insulation layer, a first conductive layer, a third insulation layer, a second conductive layer, and a fourth insulation layer are sequentially formed. The pattern of the semiconductor layer may at least include a first active connection line 10, a second active connection line 20, a first active layer 11 to a ninth active layer 19. The pattern of the first conductive layer may at least include a first gate electrode 21, a second gate electrode 22, a fourth gate electrode 24, a fifth gate electrode 25, a sixth gate electrode 26, a ninth gate electrode 29, a first scan signal line 61, a first plate 71 of the first storage capacitor, and a second plate 72 of the second storage capacitor. The pattern of the second conductive layer may at least include a first light emitting signal line 31, a second light emitting signal line 32, a repair line 33, a second shielding electrode 37, a third shielding electrode 38, a fourth shielding electrode 39, a third plate 73 of the first storage capacitor, a fourth plate 74 of the second storage capacitor, a first initial signal line 81, and a second reference signal line 92. Multiple vias in the fourth insulation layer may at least include a first via V1 to a twenty-third via V23. Positions, structures and connection relationships of the above patterns are substantially the same as those of the foregoing embodiments, except that the second conductive layer of this embodiment is not provided with a first shielding electrode.

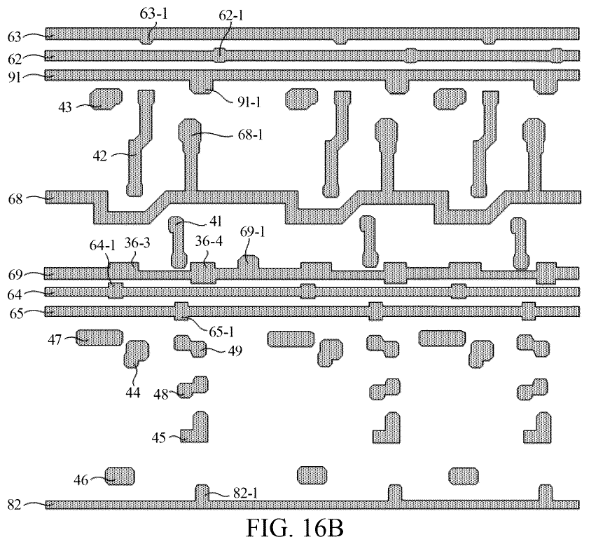

(22) A pattern of a third conductive layer is formed. In an exemplary implementation, forming the pattern of the third conductive layer may include: depositing a third conductive thin film on the base substrate on which the aforementioned patterns are formed, patterning the third conductive thin film through a patterning process to form the third conductive layer provided on the fourth insulation layer, as shown in FIG. 16A and FIG. 16B, and FIG. 16B is a schematic diagram of the third conductive layer in FIG. 16A.

In an exemplary implementation, the pattern of the third conductive layer of each circuit unit in the display substrate may include a first connection electrode 41 to a ninth connection electrode 49, a second scan signal line 62, a third scan signal line 63, a fourth scan signal line 64, a fifth scan signal line 65, a first power supply connection line 68, a second power supply connection line 69, a second initial signal line 82, and a first reference signal line 91. Structure of the third conductive layer of this exemplary embodiment is substantially the same as structure of the foregoing embodiment, except that the second power supply connection line 69 of this embodiment is between the first power supply connection line 68 and the fourth scan signal line 64, and the third conductive layer is provided with the first shielding electrode 36, and the first shielding electrode 36 and the second power supply connection line 69 are interconnected to form an integral structure.

In an exemplary implementation, the second power supply connection line 69 may be on a side of the third plate 73 in the second direction Y and between the first power supply connection line 68 and the fourth scan signal line 64. A second power supply connection block 69-1 is provided on a side of the second power supply connection line 69 close to the first power supply connection line 68. A first end of the second power supply connection block 69-1 is connected to the second power supply connection line 69, a second end of the second power supply connection block 69-1 extends towards the first power supply connection line 68, and the second power supply connection block 69-1 is configured to be connected to a second power supply line to be formed subsequently. In an exemplary implementation, the second power supply connection block 69-1 may be provided between a first circuit unit and a second circuit unit.

In an exemplary implementation, the third conductive layer of at least one circuit unit may further include a first shielding electrode 36, and the first shielding electrode 36 is connected to the second power supply connection line 69. An orthographic projection of the first shielding electrode 36 on the base substrate is at least partially overlapped with an orthographic projection of the semiconductor layer between the two gate electrodes of the first transistor T1 on the base substrate, and the orthographic projection of the first shielding electrode 36 on the base substrate is at least partially overlapped with an orthographic projection of the semiconductor layer between the two gate electrodes of the second transistor T2 on the base substrate. In an exemplary implementation, the first shielding electrode 36 is configured to shield the influence of the data voltage jump on the first transistor T1 and the second transistor T2, avoid the data voltage jump from affecting the normal operation of the pixel drive circuit, and improve the display effect.

In an exemplary implementation, the first shielding electrode 36 may include a first sub-electrode 36-3 and a second sub-electrode 36-4, and the first sub-electrode 36-3 and the second sub-electrode 36-4 may be in rectangular shapes. A first end of the first sub-electrode 36-3 is connected to the second power supply connection line 69, and a second end of the first sub-electrode 36-3 extends in a direction away from the second power supply connection line 69, i.e., in the opposite direction of the second direction Y. An orthographic projection of the second end of the first sub-electrode 36-3 on the base substrate is at least partially overlapped with an orthographic projection of the semiconductor layer between the two gate electrodes of the first transistor T1 in this circuit unit on the base substrate. A first end of the second sub-electrode 36-4 is connected to the second power supply connection line 69, and a second end of the second sub-electrode 36-4 extends in a direction away from the second power supply connection line 69. An orthographic projection of the second end of the second sub-electrode 36-4 on the base substrate is at least partially overlapped with an orthographic projection of the semiconductor layer between the two gate electrodes of the second transistor T2 in this circuit unit on the base substrate.

In some possible exemplary implementations, the middle of the first sub-electrode 36-3 is connected to the second power supply connection line 69, a first end of the first sub-electrode 36-3 extends in the opposite direction of the second direction Y, and a second end of the first sub-electrode 36-3 extends in the second direction Y. An orthographic projection of the first end and the second end of the first sub-electrode 36-3 on the base substrate is at least partially overlapped with an orthographic projection of the semiconductor layer between the two gate electrodes of the first transistor T1 in this circuit unit on the base substrate.

In some possible exemplary implementations, the middle of the second sub-electrode 36-4 is connected to the second power supply connection line 69, a first end of the second sub-electrode 36-4 extends in the opposite direction of the second direction Y, and a second end of the second sub-electrode 36-4 extends in the second direction Y. An orthographic projection of the first end and the second end of the second sub-electrode 36-4 on the base substrate is at least partially overlapped with an orthographic projection of the semiconductor layer between the two gate electrodes of the second transistor T2 in this circuit unit on the base substrate.

In an exemplary implementation, the first shielding electrode 36 and the second power supply connection line 69 are interconnected to form an integral structure.

(23) Patterns of a fifth insulation layer and a fourth conductive layer are formed as shown in FIG. 14. Positions, structures, and connection relationships of the above patterns are substantially the same as those of the foregoing embodiments and will not be described herein.

The subsequent manufacturing process may include forming a pattern of a first planarization layer. Multiple anode vias are provided in the first planarization layer, an orthographic projection of an anode via on the base substrate is within a range of an orthographic projection of an anode connection electrode on the base substrate, the first planarization layer in the anode via is removed to expose a surface of the anode connection electrode, and the anode via is configured to be connected to an anode to be formed subsequently to the anode connection electrode through the anode via.

At this point, the drive circuit layer of this embodiment is manufactured on the base substrate. In an exemplary implementation, after manufacturing of the drive circuit layer is completed, a light emitting structure layer and an encapsulation structure layer may be sequentially manufactured on the drive circuit layer, which will not be repeated herein.

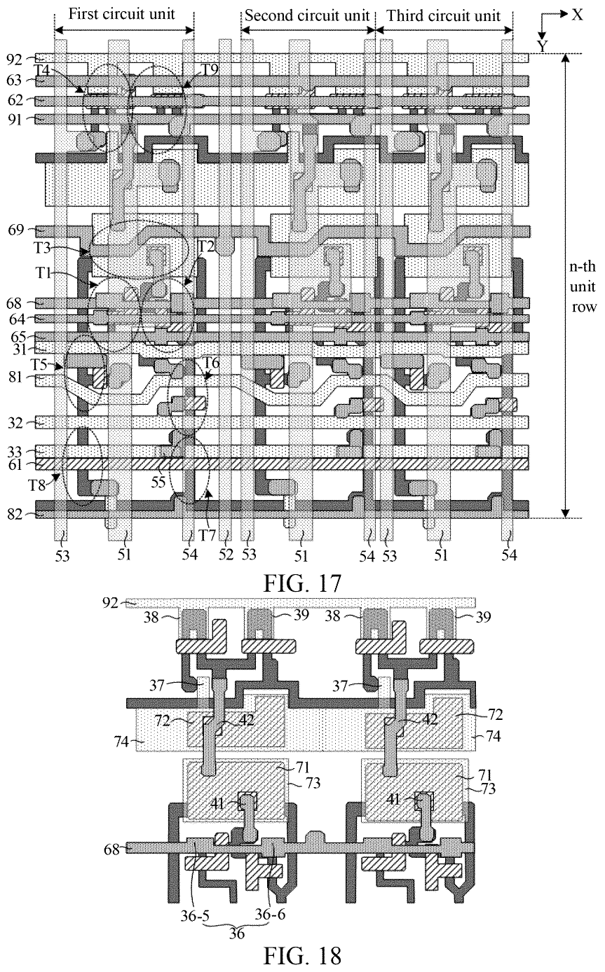

FIG. 17 is a schematic diagram of a planar structure of another display substrate according to an exemplary embodiment of the present disclosure, illustrating a structure of pixel drive circuits in three circuit units (a first circuit unit, a second circuit unit, and a third circuit unit) in the display substrate. As shown in FIG. 17, a main body structure of the pixel drive circuit of this exemplary embodiment is substantially the same as a main body structure of the foregoing embodiment, except that the first power supply connection line 68 of this embodiment is between the second power supply connection line 69 and the fourth scan signal line 64, and the first shielding electrode 36 and the first power supply connection line 68 are interconnected to form an integral structure.

FIG. 18 is an enlarged view of regions of a first storage capacitor and a second storage capacitor in FIG. 17. As shown in FIG. 18, at least one circuit unit may further include a first shielding electrode 36, and the first shielding electrode 36 is connected to the first power supply connection line 68. An orthographic projection of the first shielding electrode 36 on the base substrate is at least partially overlapped with the orthographic projection of the node between the two gate electrodes of the first transistor T1 on the base substrate, and the orthographic projection of the first shielding electrode 36 on the base substrate is at least partially overlapped with the orthographic projection of the node between the two gate electrodes of the second transistor T2 on the base substrate. In an exemplary implementation, the first shielding electrode 36 is configured to shield the influence of the data voltage jump on the first transistor T1 and the second transistor T2, avoid the data voltage jump from affecting the normal operation of the pixel drive circuit, and improve the display effect.

In an exemplary implementation, the first shielding electrode 36 includes a third sub-electrode 36-5 and a fourth sub-electrode 36-6. A first end of the third sub-electrode 36-5 is connected to the first power supply connection line 68, and a second end of the third sub-electrode 36-5 extends in the direction away from the first power supply connection line 68, i.e., in the opposite direction of the second direction Y. An orthographic projection of the second end of the third sub-electrode 36-5 on the base substrate is at least partially overlapped with the orthographic projection of the node between the two gate electrodes of the first transistor T1 in this circuit unit on the base substrate. A first end of the fourth sub-electrode 36-6 is connected to the first power supply connection line 68, a second end of the fourth sub-electrode 36-6 extends in the direction away from the first power supply connection line 68, and an orthographic projection of the second end of the fourth sub-electrode 36-6 on the base substrate is at least partially overlapped with the orthographic projection of the node between the two gate electrodes of the second transistor T2 in this circuit unit on the base substrate.

In some possible exemplary implementations, the middle of the third sub-electrode 36-5 is connected to the first power supply connection line 68, the first end of the third sub-electrode 36-5 extends in the opposite direction of the second direction Y, and the second end of the third sub-electrode 36-5 extends in the second direction Y. An orthographic projection of the first end and the second end of the third sub-electrode 36-5 on the base substrate is at least partially overlapped with the orthographic projection of the node between the two gate electrodes of the first transistor T1 in this circuit unit on the base substrate.

In some possible exemplary implementations, the middle of the fourth sub-electrode 36-6 is connected to the first power supply connection line 68, the first end of the fourth sub-electrode 36-6 extends in the opposite direction of the second direction Y, and the second end of the fourth sub-electrode 36-6 extends in the second direction Y. An orthographic projection of the first end and the second end of the fourth sub-electrode 36-6 on the base substrate is at least partially overlapped with the orthographic projection of the node between the two gate electrodes of the second transistor T2 in this circuit unit on the base substrate.

In an exemplary implementation, the first shielding electrode 36 and the first power supply connection line 68 are interconnected to form an integral structure.

In an exemplary implementation, at least one circuit unit may further include a second shielding electrode 37, a third shielding electrode 38, and a fourth shielding electrode 39, and shapes, positions, and connection structures of the second shielding electrode 37, the third shielding electrode 38, and the fourth shielding electrode 39 are substantially the same as those of the foregoing embodiments.

Exemplary description is made below through a manufacturing process of a display substrate. In an exemplary implementation, taking three circuit units in the n-th unit row as an example, the manufacturing process of the display substrate of this embodiment may include the following operations.

(31) Patterns of a first insulation layer, a semiconductor layer, a second insulation layer, a first conductive layer, a third insulation layer, a second conductive layer, and a fourth insulation layer are formed sequentially. The pattern of the semiconductor layer may at least include a first active connection line 10, a second active connection line 20, and a first active layer 11 to a ninth active layer 19. The pattern of the first conductive layer may at least include a first gate electrode 21, a second gate electrode 22, a fourth gate electrode 24, a fifth gate electrode 25, a sixth gate electrode 26, a ninth gate electrode 29, a first scan signal line 61, a first plate 71 of the first storage capacitor, and a second plate 72 of the second storage capacitor. The pattern of the second conductive layer may at least include a first light emitting signal line 31, a second light emitting signal line 32, a repair line 33, a second shielding electrode 37, a third shielding electrode 38, a fourth shielding electrode 39, a third plate 73 of the first storage capacitor, a fourth plate 74 of the second storage capacitor, a first initial signal line 81, and a second reference signal line 92. Multiple vias in the fourth insulation layer may at least include a first via V1 to a twenty-third via V23. Positions, structures and connection relationships of the above patterns are substantially the same as those of the foregoing embodiments, except that the first shielding electrode is not provided on the second conductive layer of this embodiment, and the thirteenth via V13 is configured such that the connection electrode to be formed subsequently is connected to the fourth plate 74 through the thirteenth via V13.

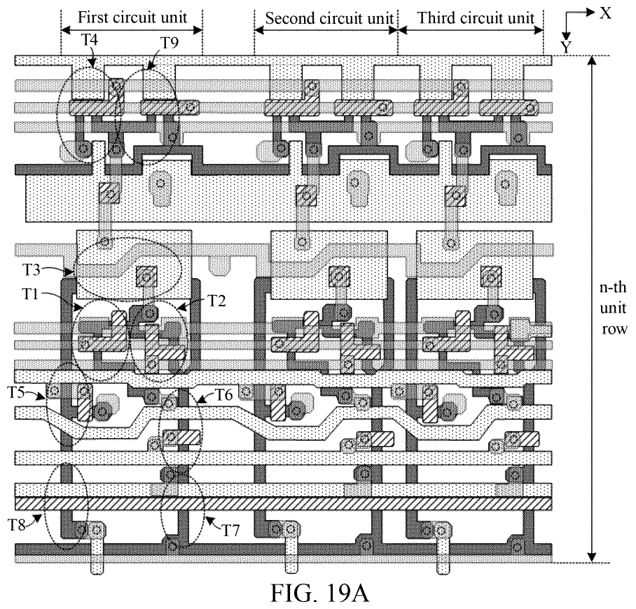

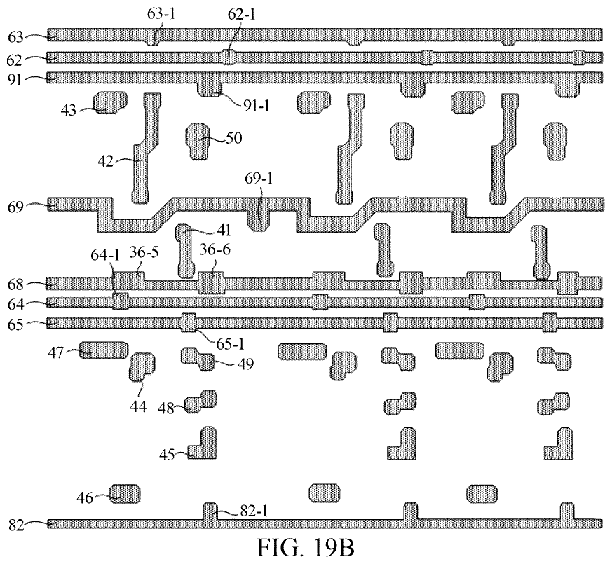

(32) A pattern of a third conductive layer is formed. In an exemplary implementation, forming the pattern of the third conductive layer may include: depositing a third conductive thin film on the base substrate on which the aforementioned patterns are formed, patterning the third conductive thin film through a patterning process to form the third conductive layer provided on the fourth insulation layer, as shown in FIG. 19A and FIG. 19B, and FIG. 19B is a schematic diagram of the third conductive layer in FIG. 19A.

In an exemplary implementation, the pattern of the third conductive layer of each circuit unit in the display substrate may include a first connection electrode 41 to a tenth connection electrode 50, a second scan signal line 62, a third scan signal line 63, a fourth scan signal line 64, a fifth scan signal line 65, a first power supply connection line 68, a second power supply connection line 69, a second initial signal line 82, and a first reference signal line 91. Except for the tenth connection electrode 50, the first power supply connection line 68, and the second power supply connection line 69, shapes, positions, and connection structure relationships of the above structures are substantially the same as those of the foregoing embodiments and will not be described herein.

In an exemplary implementation, the first power supply connection line 68 is between the second power supply connection line 69 and the fourth scan signal line 64, and the first shielding electrode 36 and the first power supply connection line 68 are interconnected to from an integral structure.

In an exemplary implementation, the first power supply connection line 68 may be on a side of the third plate 73 in the second direction Y. The second power supply connection line 69 may be between the first power supply connection line 68 and the first reference signal line 91.

In an exemplary implementation, each circuit unit may further include a first shielding electrode 36, and the first shielding electrode 36 is connected to the first power supply connection line 68. An orthographic projection of the first shielding electrode 36 on the base substrate is at least partially overlapped with an orthographic projection of a semiconductor layer between the two gate electrodes of the first transistor T1 on the base substrate, and the orthographic projection of the first shielding electrode 36 on the base substrate is at least partially overlapped with an orthographic projection of the semiconductor layer between the two gate electrodes of the second transistor T2 on the base substrate. In an exemplary implementation, the first shielding electrode 36 is configured to shield the influence of the data voltage jump on the first transistor T1 and the second transistor T2, avoid the data voltage jump from affecting the normal operation of the pixel drive circuit, and improve the display effect.

In an exemplary implementation, the first shielding electrode 36 includes a third sub-electrode 36-5 and a fourth sub-electrode 36-6, and the third sub-electrode 36-5 and the fourth sub-electrode 36-6 may be in rectangular shapes. A first end of the third sub-electrode 36-5 is connected to the first power supply connection line 68, and a second end of the third sub-electrode 36-5 extends in the direction away from the first power supply connection line 68, i.e., in the opposite direction of the second direction Y. An orthographic projection of the second end of the third sub-electrode 36-5 on the base substrate is at least partially overlapped with the orthographic projection of the semiconductor layer between the two gate electrodes of the first transistor T1 in this circuit unit on the base substrate. A first end of the fourth sub-electrode 36-6 is connected to the first power supply connection line 68, a second end of the fourth sub-electrode 36-6 extends in the direction away from the first power supply connection line 68, and an orthographic projection of the second end of the fourth sub-electrode 36-6 on the base substrate is at least partially overlapped with the orthographic projection of the semiconductor layer between the two gate electrodes of the second transistor T2 in this circuit unit on the base substrate.

In some possible exemplary implementations, the middle of the third sub-electrode 36-5 is connected to the first power supply connection line 68, a first end of the third sub-electrode 36-5 extends in the opposite direction of the second direction Y, and a second end of the third sub-electrode 36-5 extends in the second direction Y. An orthographic projection of the first end and the second end of the third sub-electrode 36-5 on the base substrate is at least partially overlapped with the orthographic projection of the semiconductor layer between the two gate electrodes of the first transistor T1 in this circuit unit on the base substrate.

In some possible exemplary implementations, the middle of the fourth sub-electrode 36-6 is connected to the first power supply connection line 68, a first end of the fourth sub-electrode 36-6 extends in the opposite direction of the second direction Y, and a second end of the fourth sub-electrode 36-6 extends in the second direction Y. An orthographic projection of the first end and the second end of the fourth sub-electrode 36-6 on the base substrate is at least partially overlapped with the orthographic projection of the semiconductor layer between the two gate electrodes of the second transistor T2 in this circuit unit on the base substrate.

In an exemplary implementation, the first shielding electrode 36 and the first power supply connection line 68 are interconnected to form an integral structure.

In an exemplary implementation, the tenth connection electrode 50 may be in a rectangular shape, the tenth connection electrode 50 may be between the first reference signal line 91 and the second power supply connection line 69, and the tenth connection electrode 50 is connected to the fourth plate 74 through the thirteenth via V13. In an exemplary implementation, the tenth connection electrode 50 is configured to be connected to a first power supply line to be formed subsequently.

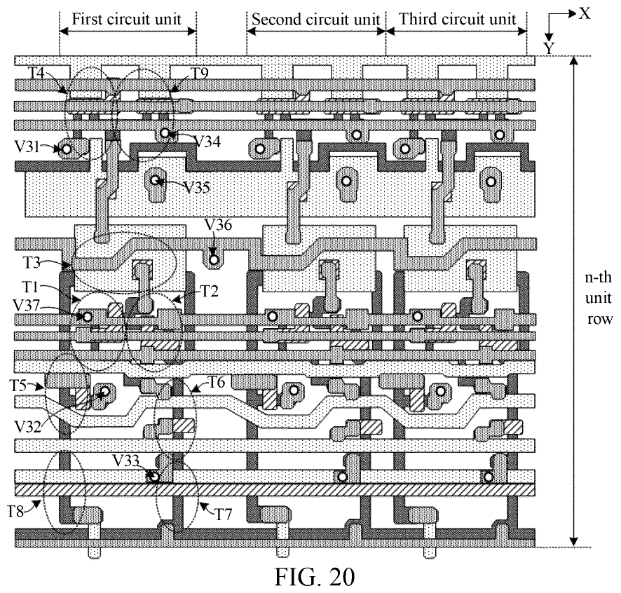

(33) A pattern of a fifth insulation layer is formed. In an exemplary implementation, forming the pattern of the fifth insulation layer may include: depositing a fifth insulation thin film on the base substrate on which the aforementioned patterns are formed, patterning the fifth insulation thin film through a patterning process to form the fifth insulation layer that covers the third conductive layer, wherein multiple vias are provided on each circuit unit, as shown in FIG. 20.

In an exemplary implementation, multiple vias of each circuit unit in the display substrate at least include a thirty-first via V31 to a thirty-fifth via V35, a thirty-seventh via V37, and positions, structures and connection relationships of the thirty-first via V31 to the thirty-fourth via V34 are substantially the same as those of the foregoing embodiments, and will not be described herein.

In an exemplary implementation, an orthographic projection of the thirty-fifth via V35 on the base substrate is within a range of an orthographic projection of the tenth connection electrode 50 on the base substrate, the fifth insulation layer in the thirty-fifth via V35 is removed to expose a surface of the tenth connection electrode 50, and the thirty-fifth via V35 is configured such that a first power supply line to be formed subsequently is connected to the tenth connection electrode 50 through the thirty-fifth via V35.

In an exemplary implementation, an orthographic projection of the thirty-seventh via V37 on the base substrate may be within a range of an orthographic projection of the third sub-electrode 36-5 on the base substrate, the fifth insulation layer in the thirty-seventh via V37 is removed to expose a surface of the third sub-electrode 36-5, and the thirty-seventh via V37 is configured to be connected to a first power supply line to be formed subsequently to the first power supply connection line 68 through the thirty-seventh via V37. The third sub-electrode 36-5 is connected to the first power supply connection line 68, thereby realizing that the first power supply connection line 68, whose main body portion extends along the first direction X, and the first power supply line 51, whose main body portion extends along the second direction Y, are interconnected, so that the first power supply line 51 and the first power supply connection line 68 form a mesh structure for transmitting a first power supply signal on the display substrate, which can not only effectively reduce a resistance of the first power supply line 51 and reduce a voltage drop of the first power supply signal, but also effectively improve the uniformity of the first power supply signal in the display substrate, effectively improve the display effect and the display quality.

In an exemplary implementation, a thirty-sixth via V36 may further be included in at least one circuit unit. An orthographic projection of the thirty-sixth via V36 on the base substrate is within an orthographic projection of the second power supply connection block 69-1 of the second power supply connection line 69 on the base substrate. The fifth insulation layer in the thirty-sixth via V36 is removed to expose a surface of the second power supply connection block 69-1. The thirty-sixth via V36 is configured to be connected to the second power supply line to be formed subsequently to the second power supply connection block 69-1 through the thirty-sixth via V36. In an exemplary implementation, the thirty-sixth via V36 may be between a first circuit unit and a second circuit unit.

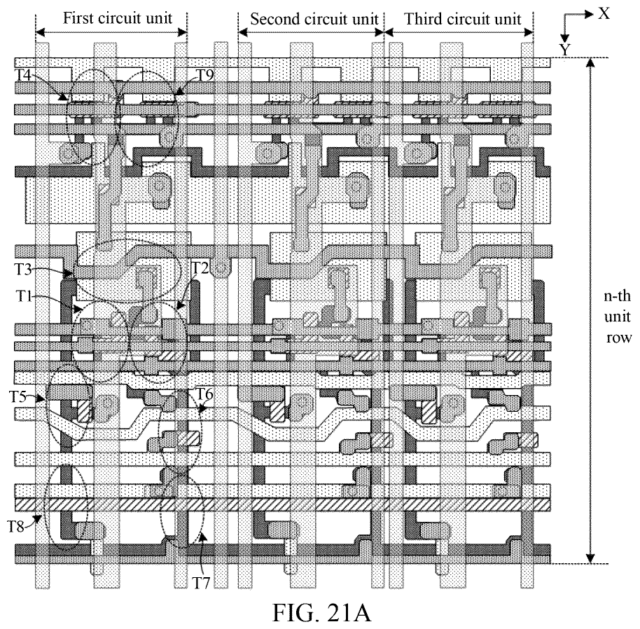

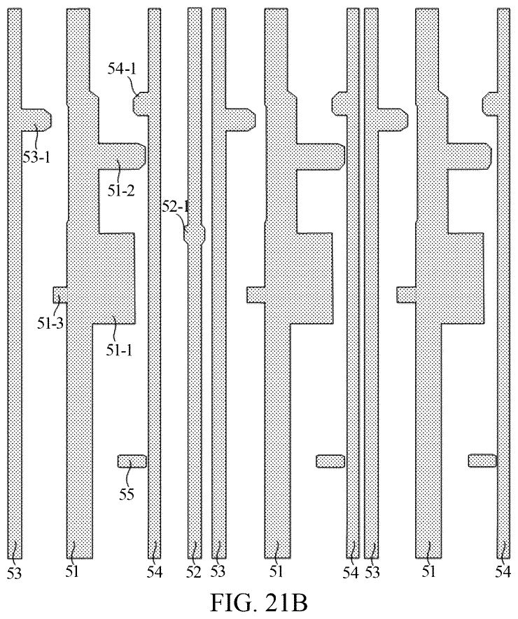

(34) A pattern of a fourth conductive layer is formed. In an exemplary implementation, forming the pattern of the fourth conductive layer may include: depositing a fourth conductive thin film on the base substrate on which the aforementioned patterns are formed, patterning the fourth conductive thin film through a patterning process to form the fourth conductive layer provided on the fifth insulation layer, as shown in FIG. 21A and FIG. 21B, and FIG. 21B is a schematic diagram of the fourth conductive layer in FIG. 21A.

In an exemplary implementation, the pattern of the fourth conductive layer of each circuit unit in the display substrate may include a first power supply line 51, a data signal line 53, a reference signal connection line 54, and an anode connection electrode 55. Positions, structures, and connection relationships of the data signal line 53, the reference signal connection line 54, and the anode connection electrode 55 are substantially the same as those of the foregoing embodiments and will not be described herein.

In an exemplary implementation, a power supply shielding block 51-1 is provided on a side of the first power supply line 51 close to the reference signal connection line 54, a first end of the power supply shielding block 51-1 is connected to the first power supply line 51, and a second end of the power supply shielding block 51-1 extends towards the reference signal connection line 54. The power supply shielding block 51-1 may be in a rectangular shape, and an orthographic projection of the power supply shielding block 51-1 on the base substrate is at least partially overlapped with an orthographic projection of the first connection electrode 41 on the base substrate. Since the first connection electrode 41 serves as the first node N1 in the pixel drive circuit, the power supply shielding block 51-1 with constant voltage can effectively shield the influence of the other signals in the pixel drive circuit on the first node N1, thereby avoiding other signals (such as data voltage jump) from affecting the potential of the first node N1 in the pixel drive circuit and improving the display effect.

In an exemplary implementation, the first power supply line 51 and the power supply shielding block 51-1 may be interconnected to form an integral structure.

In an exemplary implementation, the orthographic projection of the power supply shielding block 51-1 on the base substrate may include the orthographic projection of the first connection electrode 41 on the base substrate.

In an exemplary implementation, a third power supply connection block 51-2 is provided on a side of the first power supply line 51 close to the reference signal connection line 54. The third power supply connection block 51-2 may be in a strip shape extending along the first direction X, a first end of the third power supply connection block 51-2 is connected to the first power supply line 51, and a second end of the third power supply connection block 51-2 extends towards the reference signal connection line 54, and is connected to the tenth connection electrode 50 through the thirty-fifth via V35.

In an exemplary implementation, the first power supply line 51 and the third power supply connection block 51-2 may be interconnected to form an integral structure.

In an exemplary implementation, the pattern of the fourth conductive layer of each circuit unit in the display substrate may further include a fifth power supply connection block 51-3. A first end of the fifth power supply connection block 51-3 is connected to the first power supply line 51, a second end of the fifth power supply connection block 51-3 extends towards the data signal line 53 in the circuit unit, and the fifth power supply connection block 51-3 may be in a rectangular shape. The fifth power supply connection block 51-3 is connected to the first power supply connection line 68 through the thirty-seventh via V37. The fifth power supply connection block 51-3 is connected to the first power supply line 51, thereby realizing that the first power supply connection line 68, whose main body portion extends along the first direction X, and the first power supply line 51, whose main body portion extends along the second direction Y, are interconnected, so that the first power supply line 51 and the first power supply connection line 68 form a mesh structure for transmitting a first power supply signal on the display substrate, which can not only effectively reduce the resistance of the first power supply line 51 and reduce the voltage drop of the first power supply signal, but also effectively improve the uniformity of the first power supply signal in the display substrate, effectively improve the display effect and the display quality.

The subsequent manufacturing process may include forming a pattern of a first planarization layer. Multiple anode vias are provided in the first planarization layer, an orthographic projection of an anode via on the base substrate is within a range of an orthographic projection of an anode connection electrode on the base substrate, the first planarization layer in the anode via is removed to expose a surface of the anode connection electrode, and the anode via is configured to be connected to the anode to be formed subsequently to the anode connection electrode through the anode via.

At this point, the drive circuit layer of this embodiment is manufactured on the base substrate. In an exemplary implementation, after manufacturing of the drive circuit layer is completed, a light emitting structure layer and an encapsulation structure layer may be sequentially manufactured on the drive circuit layer, which will not be repeated herein.

As can be seen from the structure and manufacturing process of the display substrate of this embodiment described above, in an embodiment of the present disclosure, by providing the first power supply connection line, the second power supply connection line, the first power supply line, and the second power supply line, the first power supply line and the first power supply connection line are interconnected, so that the first power supply line and the first power supply connection line form a mesh structure for transmitting the first power supply signal on the display substrate, and the second power supply line and the second power supply connection line are interconnected, so that the second power supply line and the second power supply connection line from a mesh structure for transmitting the second power supply signal on the display substrate, which can not only effectively reduce the resistances of the first power supply line and the second power supply line, reduce the voltage drop of the first power supply signal and the second power supply signal, but also effectively improve the uniformity of the first power signal and the second power signal in the display substrate and improve the display effect and the display quality. In an embodiment of the present disclosure, by providing the shielding electrode to be connected to the first power supply connection line or the second power supply connection line with a constant potential, which the nodes between the two gate electrodes of the transistors with the double-gate structure can effectively shielded, thus ensuring the normal operation of the pixel drive circuit and improving the display effect.

In an embodiment of the present disclosure, by providing the first reference signal line and the reference signal connection line, and the first reference signal line and the reference signal connection line are interconnected, so that the first reference signal line and the reference signal connection line form a mesh structure for transmitting the first reference signal on the display substrate, which can not only effectively reduce the resistance of the first reference signal line and reduce the voltage drop of the first reference signal, but also effectively improve the uniformity of the first reference signal in the display substrate, effectively improve the display uniformity, and improve the display effect and the display quality.

In an embodiment of the present disclosure, by providing the first active connection line of the semiconductor layer and the first reference signal line of the third conductive layer to form a signal line with a double-layer structure, which can effectively reduce the voltage drop of the reference signal, is beneficial to improving the uniformity of the panel, avoids the poor display of the display substrate and ensures the display effect of the display substrate.

In an embodiment of the present disclosure, by providing the first shielding electrode, the second shielding electrode, the third shielding electrode and the fourth shielding electrode, which can shield the influence of data voltage jump on the first transistor T1, the second transistor T2, the fourth transistor T4, the ninth transistor T9 and key nodes, avoid the influence of data voltage jump on the normal operation of the pixel drive circuit, and improve the display effect.

In an embodiment of the present disclosure, by providing that the first power supply line and the power supply shielding block to shield the first node N1 and the fifth node N5 of the pixel drive circuit, other signals can be effectively avoided from affecting the potentials of the first node N1 and the fifth node N5 of the pixel drive circuit to improve the display effect.

In an embodiment of the present disclosure, by providing that the second power supply connection line is overlapped with the first initial signal line, the wiring layout is more rational.

The manufacturing process in the present disclosure may be compatible well with an existing manufacturing process, is simple in process implementation, is easy to implement, and has a high production efficiency, a low production cost, and a high yield.

In an exemplary implementation mode, the base substrate may be a flexible base substrate, or a rigid base substrate. The rigid base substrate may be, but is not limited to, one or more of glass and quartz. The flexible base substrate may be, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber. In an exemplary implementation, the flexible base substrate may include a first flexible material layer, a first inorganic material layer, a semiconductor layer, a second flexible material layer, and a second inorganic material layer which are stacked, wherein materials of the first flexible material layer and the second flexible material layer may be Polyimide (PI), Polyethylene Terephthalate (PET), or a surface-treated polymer soft film, or the like, materials of the first inorganic material layer and the second inorganic material layer may be Silicon Nitride (SiNₓ) or Silicon Oxide (SiOₓ), or the like, for improving a water and oxygen resistance capability of the base substrate, and a material of the semiconductor layer may be amorphous silicon (a-si).

In an exemplary implementation, the first conductive layer, the second conductive layer, the third conductive layer, and the fourth conductive layer may be made of a metal material, such as any one or more of Argentum (Ag), Copper (Cu), Aluminum (Al), and Molybdenum (Mo), or an alloy material of the above metals, such as an Aluminum Neodymium alloy (AlNd) or a Molybdenum Niobium alloy (MoNb), and may be in a single-layer structure or a multi-layer composite structure, such as Mo/Cu/Mo. The first insulation layer, the second insulation layer, the third insulation layer, the fourth insulation layer, and the fifth insulation layer may be made of any one or more of Silicon Oxide (SiOₓ), Silicon Nitride (SiNₓ), and Silicon Oxynitride (SiON), and may be a single layer, a multi-layer, or a composite layer. The first insulation layer is referred to as a buffer layer, the second insulation layer and the third insulation layer are referred to as gate insulation (GI) layers, the fourth insulation layer is referred to as an interlayer dielectric (ILD) layer, and the fifth insulation layer is referred to as a passivation (PVX) layer. The first planarization layer may be made through an organic material such as resin. An active layer may be made of a material such as amorphous Indium Gallium Zinc Oxide (a-IGZO), Zinc Oxynitride (ZnON), Indium Zinc Tin Oxide (IZTO), amorphous Silicon (a-Si), poly-crystalline Silicon (p-Si), hexathiophene, or polythiophene. That is, the present disclosure is applicable to a transistor that is manufactured based on an oxide technology, a silicon technology, or an organic matter technology. The aforementioned structure shown in the present disclosure and the manufacturing process therefor are merely exemplary description. In an exemplary implementation, corresponding structures may be changed and patterning processes may be added or reduced according to actual needs, which is not limited herein in the present disclosure.

In an exemplary implementation, the display substrate according to the present disclosure may be applied to a display device with a pixel drive circuit, such as an OLED, a quantum dot display (QLED), a light emitting diode display (Micro LED or Mini LED), or a Quantum Dot Light Emitting Diode display (QDLED), which is not limited herein in the present disclosure.

The present disclosure further provides a display device, the display device including the display substrate in anyone of the aforementioned embodiments. The display device may be any product or component with a display function, such as a mobile phone, a tablet computer, a television, a display, a laptop computer, a digital photo frame, or a navigator, which is not limited in the embodiments of the present disclosure.

Although implementations disclosed in the present disclosure are described as above, the described contents are only implementations which are used for facilitating understanding of the present disclosure, but are not intended to limit the present disclosure. Any skilled person in the art to which the present disclosure pertains may make any modification and variation in forms and details of implementations without departing from the spirit and scope of the present disclosure. However, the patent protection scope of the present disclosure should be subject to the scope defined in the appended claims.

1. A display substrate, comprising a drive circuit layer provided on a base substrate and a light emitting structure layer provided on a side of the drive circuit layer away from the base substrate, wherein the drive circuit layer at least comprises a plurality of circuit units, at least one first power supply connection line and at least one second power supply connection line which extend along a first direction, at least one first power supply line and at least one second power supply line which extend along a second direction, at least one circuit unit comprises a pixel drive circuit, a first power supply line is connected to the pixel drive circuit, the first power supply line is configured to continuously provide a high-level signal to the pixel drive circuit, the light emitting structure layer at least comprises a plurality of light emitting units, at least one light emitting unit comprises a cathode, a second power supply line is connected to the cathode, the second power supply line is configured to continuously provide a low-level signal to the cathode; the at least one first power supply line is connected to the at least one first power supply connection line to form a mesh structure for transmitting a first power supply signal, the at least one second power supply line is connected to the at least one second power supply connection line to form a mesh structure for transmitting a second power supply signal, and the first direction intersects with the second direction;
wherein the pixel drive circuit comprises a first shielding electrode and at least one transistor with a double-gate structure, an orthographic projection of the first shielding electrode on the base substrate is at least partially overlapped with an orthographic projection of a node between two gate electrodes of a transistor with the double-gate structure on the base substrate; the first shielding electrode is connected to a first power supply connection line; or, the first shielding electrode is connected to a second power supply connection line.

2. The display substrate according to claim 1, wherein the at least one transistor with the double-gate structure comprises a first initialization transistor and a compensation transistor, a first electrode of the first initialization transistor is connected to a first initial signal line, a first electrode of the compensation transistor is connected to a second electrode of the first initialization transistor, the orthographic projection of the first shielding electrode on the base substrate is at least partially overlapped with an orthographic projection of a node between two gate electrodes of the first initialization transistor on the base substrate, and the orthographic projection of the first shielding electrode on the base substrate is at least partially overlapped with an orthographic projection of a node between two gate electrodes of the compensation transistor on the base substrate.

3. The display substrate according to claim 2, wherein the first shielding electrode and the second power supply connection line are interconnected to form an integral structure.

4. The display substrate according to claim 3, wherein the second power supply connection line is on a side of the first power supply connection line close to the first initialization transistor and the compensation transistor.

5. The display substrate according to claim 4, wherein the first shielding electrode at least comprises a first sub-electrode and a second sub-electrode, a first end of the first sub-electrode is connected to the second power supply connection line, a second end of the first sub-electrode extends in a direction close to the first power supply connection line, an orthographic projection of the second end of the first sub-electrode on the base substrate is at least partially overlapped with the orthographic projection of the node between the two gate electrodes of the first initialization transistor on the base substrate; a first end of the second sub-electrode is connected to the second power supply connection line, a second end of the second sub-electrode extends in the direction close to the first power supply connection line, and an orthographic projection of the second end of the second sub-electrode on the base substrate is at least partially overlapped with the orthographic projection of the node between the two gate electrodes of the compensation transistor on the base substrate.

6. The display substrate according to claim 2, wherein the first shielding electrode and the first power supply connection line are interconnected to form an integral structure.

7. The display substrate according to claim 6, wherein the first power supply connection line is on a side of the second power supply connection line close to the first initialization transistor and the compensation transistor.

8. The display substrate according to claim 7, wherein the first shielding electrode at least comprises a third sub-electrode and a fourth sub-electrode, a first end of the third sub-electrode is connected to the first power supply connection line, a second end of the third sub-electrode extends in a direction close to the second power supply connection line, and an orthographic projection of the second end of the third sub-electrode on the base substrate is at least partially overlapped with the orthographic projection of the node between the two gate electrodes of the first initialization transistor on the base substrate; a first end of the fourth sub-electrode is connected to the first power supply connection line, a second end of the fourth sub-electrode extends in the direction close to the second power supply connection line, and an orthographic projection of the second end of the fourth sub-electrode on the base substrate is at least partially overlapped with the orthographic projection of the node between the two gate electrodes of the compensation transistor on the base substrate.

9. The display substrate according to claim 2, wherein the pixel drive circuit further comprises a first storage capacitor and a second storage capacitor, the first storage capacitor at least comprises a first plate and a third plate, an orthographic projection of the first plate on the base substrate is at least partially overlapped with an orthographic projection of the third plate on the base substrate; the second storage capacitor at least comprises a second plate and a fourth plate, an orthographic projection of the second plate on the base substrate is at least partially overlapped with an orthographic projection of the fourth plate on the base substrate; the second plate is connected to the third plate, the fourth plate is connected to the first power supply connection line, and the first shielding electrode is connected to the fourth plate.

10. The display substrate according to claim 9, wherein the first shielding electrode and the fourth plate are interconnected to form an integral structure.

11. The display substrate according to claim 9, wherein the first shielding electrode comprises a first extension segment and a first shielding segment; the first extension segment is in a strip shape extending along the second direction, and the first shielding segment is in a strip shape extending along the first direction; a first end of the first extension segment is connected to the fourth plate, and a second end of the first extension segment is connected to the first shielding segment; the first shielding segment comprises a first shielding end and a in second shielding end, an orthographic projection of the first shielding end on the base substrate is at least partially overlapped with an orthographic projection of a node between two gate electrodes of a first initialization transistor in a current circuit unit on the base substrate, and an orthographic projection of the second shielding end on the base substrate is at least partially overlapped with an orthographic projection of a node between two gate electrodes of a compensation transistor in an adjacent circuit unit on the base substrate.

12. The display substrate according to claim 1, wherein the at least one transistor with the double-gate structure further comprises a data writing transistor and a first reference transistor, a first electrode of the data writing transistor is connected to a data signal line, a first electrode of the first reference transistor is connected to a first reference signal line, and a second electrode of the data writing transistor is connected to a second electrode of the first reference transistor; and
the pixel drive circuit further comprises a second shielding electrode provided between the first electrode of the data writing transistor and the second electrode of the data writing transistor.

13. The display substrate according to claim 1, wherein the at least one transistor with the double-gate structure further comprises a data writing transistor and a first reference transistor, a first electrode of the data writing transistor is connected to a data signal line, a first electrode of the first reference transistor is connected to a first reference signal line, and a second electrode of the data writing transistor is connected to a second electrode of the first reference transistor; and
the pixel drive circuit further comprises a third shielding electrode and a fourth shielding electrode, an orthographic projection of the third shielding electrode on the base substrate is at least partially overlapped with an orthographic projection of a node between two gate electrodes of the data writing transistor on the base substrate, and an orthographic projection of the fourth shielding electrode on the base substrate is at least partially overlapped with an orthographic projection of a node between two gate electrodes of the first reference transistor on the base substrate.

14. The display substrate according to claim 2, wherein an orthographic projection of the second power supply connection line on the base substrate is at least partially overlapped with an orthographic projection of the first initial signal line on the base substrate.

15. The display substrate according to claim 1, wherein on a plane perpendicular to the display substrate, the drive circuit layer comprises a plurality of conductive layers; the first power supply line and the first power supply connection line are provided in different conductive layers, and the first power supply line and the first power supply connection line are connected through a via; the second power supply line and the second power supply connection line are provided in different conductive layers, and the second power supply line and the second power supply connection line are connected through a via.

16. The display substrate according to claim 15, wherein the first power supply connection line and the second power supply connection line are provided in a same layer, and the first power supply line and the second power supply line are provided in a same layer.

17. The display substrate according to claim 15, wherein the plurality of conductive layers at least comprise a first conductive layer, a second conductive layer, a third conductive layer, and a fourth conductive layer provided sequentially in a direction away from the base substrate; the first power supply connection line and the second power supply connection line are provided in the third conductive layer, and the first power supply line and the second power supply line are provided in the fourth conductive layer.

18. The display substrate according to claim 1, wherein on a plane perpendicular to the display substrate, the drive circuit layer comprises a plurality of conductive layers; the plurality of conductive layers at least comprise a first conductive layer, a second conductive layer, and a third conductive layer provided sequentially along a direction away from the base substrate; the first shielding electrode is provided in the second conductive layer, or the first shielding electrode is provided in the third conductive layer.

19. The display substrate according to claim 18, wherein the pixel drive circuit further comprises a first storage capacitor and a second storage capacitor, the first storage capacitor at least comprises a first plate and a third plate, an orthographic projection of the first plate on the base substrate is at least partially overlapped with an orthographic projection of the third plate on the base substrate; the second storage capacitor at least comprises a second plate and a fourth plate, an orthographic projection of the second plate on the base substrate is at least partially overlapped with an orthographic projection of the fourth plate on the base substrate; the first plate and the second plate are provided in the first conductive layer, and the third plate and the fourth plate are provided in the second conductive layer.

20. A display device, comprising the display substrate according to claim 1.
